(19) United States
(12) Patent Application Publication
(10) Pub. No.: US 2024/0113166 A1
(43) Pub. Date: Apr. 4, 2024

(54) SEMICONDUCTOR DEVICES AND METHODS OF MANUFACTURING THEREOF

(71) Applicant: Taiwan Semiconductor Manufacturing Company, Ltd., Hsinch (TW)

(72) Inventors: Tzu-Ging Lin, Hsinchu City (TW); Chun-Liang Lai, Hsinchu City (TW); Yun-Chen Wu, Hsinchu City (TW); Ya-Yi Tsai, Hsinchu City (TW); Shu-Yuan Ku, Hsinchu City (TW); Shun-Hui Yang, Hsinchu City (TW)

(73) Assignee: Taiwan Semiconductor Manufacturing Company, Ltd., Hsinchu (TW)

(21) Appl. No.: 18/169,597

(22) Filed: Feb. 15, 2023

Related U.S. Application Data
(60) Provisional application No. 63/411,412, filed on Sep. 29, 2022.

(51) Int. Cl. H01L 29/06; H01L 21/8234; H01L 29/423; H01L 29/786

(52) U.S. Cl. CPC H01L 29/0673; H01L 21/823412; H01L 21/823481; H01L 29/42392; H01L 29/78696

(57) ABSTRACT

A method for fabricating semiconductor devices includes forming channel regions over a substrate. The channel regions, in parallel with one another, extend along a first lateral direction. Each channel region includes at least a respective pair of epitaxial structures. The method includes forming a gate structure over the channel regions, wherein the gate structure extends along a second lateral direction. The method includes removing, through a first etching process, a portion of the gate structure that was disposed over a first one of the channel regions. The method includes removing, through a second etching process, a portion of the first channel region. The second etching process includes one silicon etching process and one silicon oxide deposition process. The method includes removing, through a third etching process controlled based on a pulse signal, a portion of the substrate that was disposed below the removed portion of the first channel region.

### CROSS-REFERENCE TO RELATED APPLICATIONS

This application claims the benefit of and priority to U.S. Provisional Patent App. No. 63/411,412, filed Sep. 29, 2022, the entire disclosure of which is incorporated herein by reference.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an example flow chart of a method for fabricating a semiconductor device in connection with the CPODE processes described herein, in accordance with some embodiments.

FIGS. 2-29 illustrate various cross-sectional and perspective views of an example transistor device during various fabrication stages, made by the method of FIG. 1, in accordance with some embodiments.

FIGS. 30A and 30B include examples before and after cross-sectional, respectively, photographs of transistor devices that are subjected to an etching process, in accordance with some embodiments.

FIG. 31 illustrates an example cross-sectional photograph of transistor devices that are aligned when subjected to the etching processes, made by the method of FIG. 1, in accordance with some embodiments.

FIG. 32 illustrates an example cross-sectional photograph of transistor devices that are subjected to the etching processes, made by the method of FIG. 1, in accordance with some embodiments.

FIG. 33 shows an example cross-sectional photograph of transistor devices subjected to the etching processes, made by the method of at least method of FIG. 1 with an overlay showing various etching stages used to carry out the CPODE techniques that do not result in transistor damage, in accordance with some embodiments.

FIG. 34 is an example flow chart of a method for fabricating a semiconductor device, in accordance with some embodiments.

FIG. 35 shows cross-sectional photographs of transistor devices that are manufactured using CPODE techniques described herein, in accordance with some embodiments.

FIG. 36 shows an example diagram of a top view of a result of a CPODE process that is used to isolate one or more transistor devices, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, the present disclosure provides various embodiments of semiconductor device manufacturing techniques that include a number of transistors. During or after the manufacture of the transistor devices, certain transistor devices can be isolated from one another by forming “cuts” in the substrate in which the transistors are formed. For instance, an etching process or technique, such as cut polysilicon on diffusion edge (CPODE) technique, can be used to pattern transistors by truncating at least a portion of the transistors. The cuts can be filled with a dielectric material to electrically isolate the transistors from one another. However, due to overlap or shift, certain etching processes can cause damage to the epitaxial structure of the transistor(s), such as during the patterning process. To address the issue, the present techniques implement a directional etching profile, which utilizes different etching parameters when etching at different depths through the transistor devices, and/or when etching different materials or structures of the transistor devices. This etching process (sometimes referred to as cut polysilicon on diffusion edge (CPODE) technique) can be used to safely remove material from the material structures in which the transistor devices are formed without damaging the transistor devices. Through utilizing the etching process discussed herein, the damage to the epitaxial structure is minimized or avoided, minimal shallow trench isolation (STI) material is lost during the etching process, silicon (e.g., substrate) horn is minimized, and bowing of the polysilicon (PO) material of the transistor devices is avoided.

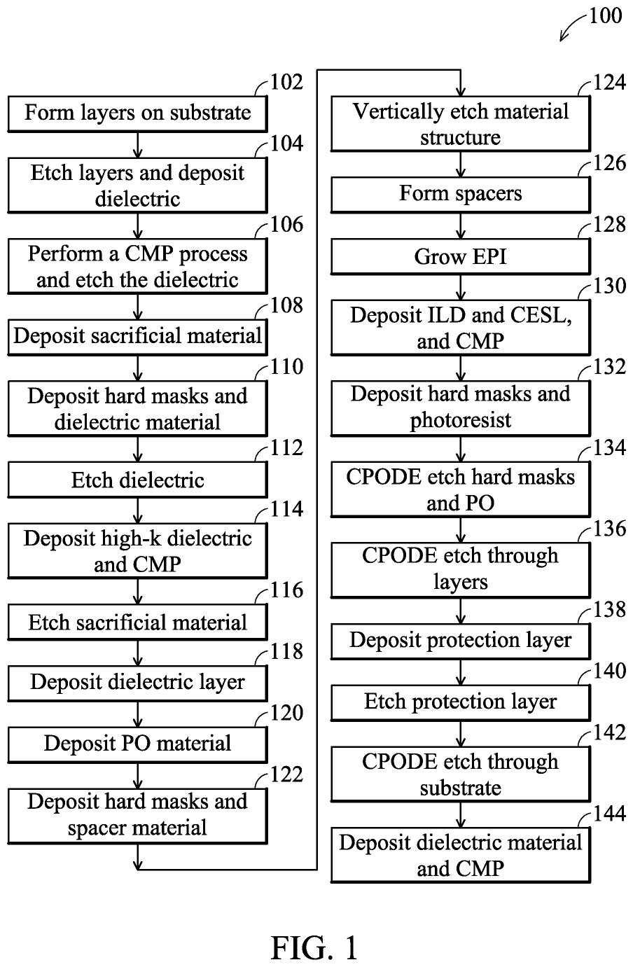

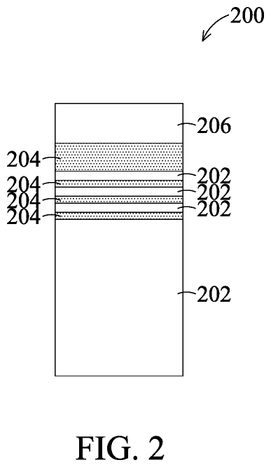

FIG. 1 illustrates a flowchart of an example method 100 for making transistor devices in connection with the CPODE processes described herein, in accordance with some embodiments. For example, at least some of the operations (or steps) of the method 100 can be used to form transistor devices, such as a nanosheet transistor devices, fin field-effect transistor (FinFET) devices, nanowire transistor devices, vertical transistor devices, or the like, and to electrically isolate the transistor devices from one another according to a predetermined design using CPODE techniques. It is noted that the method 100 is merely an example, and is not intended to limit the present disclosure. Accordingly, it is understood that additional operations may be provided before, during, and after the method 100 of FIG. 1, and that some other operations may only be briefly described herein. Additionally, operations of the method 100 may be performed in an order different from that described herein to achieve desired results. In some embodiments, operations of the method 100 may be associated with the various perspective and cross-sectional views of the transistor devices at various fabrication stages as shown in FIGS. 2-29 respectively, which will be discussed in further detail below.

In brief overview, the method 100 starts with operation 102 of forming layers on a substrate. The method 100 continues to operation 104 of etching layers and depositing dielectrics. The method 100 continues to operation 106 of performing a chemical mechanical polish (CMP) procedure and etching the dielectric. The method 100 continues to operation 108 of depositing sacrificial material. The method 100 continues to operation 110 of depositing hardmasks and dielectric material. The method 100 continues to operation 112 of etching the dielectric. The method 100 continues to operation 114 of depositing high-k dielectric and performing a CMP process. The method 100 continues to operation 116 of etching the sacrificial material. The method 100 continues to operation 118 of depositing a dielectric layer. The method 100 continues to operation 120 of depositing a polysilicon (PO) material. The method 100 continues to operation 122 of depositing hardmasks and spacer material. The method 100 continues to operation 124 of vertically etching the material structure. The method 100 continues to operation 126 of forming spacers. The method 100 continues to operation 128 of epitaxially growing semiconductor material. The method 100 continues to operation 130 of forming an interlayer dielectric (ILD), a contact etch stop layer (CESL), and performing a CMP process. The method 100 continues to operation 132 of depositing hardmasks and photoresist. The method 100 continues to operation 134 of CPODE etching hardmasks and PO. The method 100 continues to operation 136 of CPODE etching through one or more layers. The method 100 continues to operation 138 of depositing at least one protection layer. The method 100 continues to operation 140 of etching the protection layer. The method 100 continues to operation 142 of CPODE etching through substrate. The method 100 continues to operation 144 of depositing a dielectric and performing a CMP process.

As mentioned above, FIGS. 2-29 illustrate, in various cross-sectional and perspective views, a portion of three-dimensional transistor devices at various fabrication stages of the method 100 of FIG. 1. It should be understood that the process steps shown in FIGS. 2-29 may include a number of other devices such as inductors, fuses, capacitors, coils, etc., which are not shown in FIGS. 2-29, for purposes of clarity of illustration.

Corresponding to operation 102 of FIG. 1, FIG. 2 is a cross-sectional view 200 of a stack of layers that used to manufacture semiconductor devices using the techniques described herein. The stack of layers can be formed on a semiconductor substrate 202, and can include a number of alternating layers of the substrate material 202 and a first sacrificial material 204. A hardmask material 206 can be deposited on the top layer of the sacrificial material 204.

The substrate 202 may be a semiconductor substrate, such as a bulk semiconductor, a semiconductor-on-insulator (SOI) substrate, or the like, which may be doped (e.g., with a p-type or an n-type dopant) or undoped. The substrate 202 may be a wafer, such as a silicon wafer. Generally, an SOI substrate includes a layer of a semiconductor material formed on an insulator layer (not shown). The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 202 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The one or more layers of the sacrificial material 204 may be formed on the substrate material 202 using a material deposition process or an epitaxial growth process. The sacrificial material 204 can be removed in later process steps, and can be formed from a material that has different material properties than the substrate material 202, to facilitate selective removal or deposition techniques described herein. The sacrificial material 204 can be an alloy semiconductor material, such as SiGe.

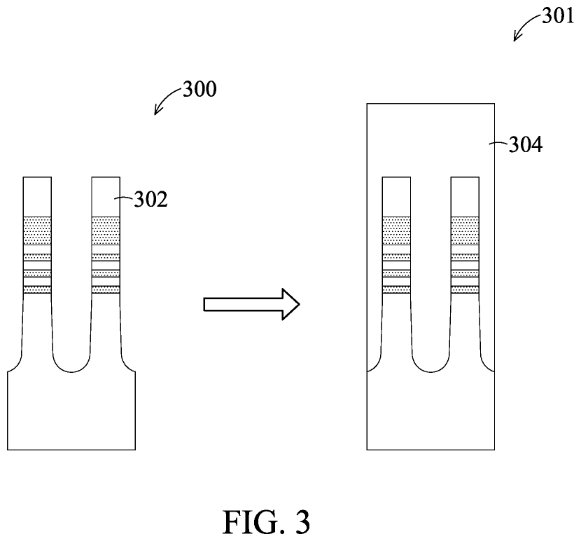

Corresponding to operation 104 of FIG. 1, FIG. 3 are cross-sectional views 300 and 301 of the stack of layers of FIG. 2, after an etching process has been applied to structures. As shown, the views 300 and 301 show the deposition of two layers of a first dielectric material 302 and a second dielectric material 304. Although two etched structures are shown, it should be appreciated that the device can include any number of etched structures which can be subsequently using an appropriate patterning and etching technique, such as while remaining within the scope of the present disclosure.

The first dielectric material 302 and the second dielectric material 304 can be any type of insulating material, including various oxides, such as silicon oxide, a nitride, or other insulators, or combinations thereof. The layer of the first dielectric material can be formed using any suitable material deposition technique, including atomic layer deposition (ALD), a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other dielectric materials and other formation processes may be used. In an example, the first dielectric material 302 or the second dielectric material 304 can be a silicon oxide. Similarly, the second dielectric material may be a different type of insulation material than the first dielectric material, and can be deposited using a suitable material deposition technique.

The first dielectric material 302 can be formed as a liner, and the second dielectric material can be deposited on top of the liner to encase the etched structures shown in the cross-sectional view 300. The first dielectric material 302 can be a liner oxide. The liner oxide (e.g., silicon oxide) may be a thermal oxide formed through a thermal oxidation of a surface layer of the substrate 202, although other suitable method may also be used to form the liner oxide.

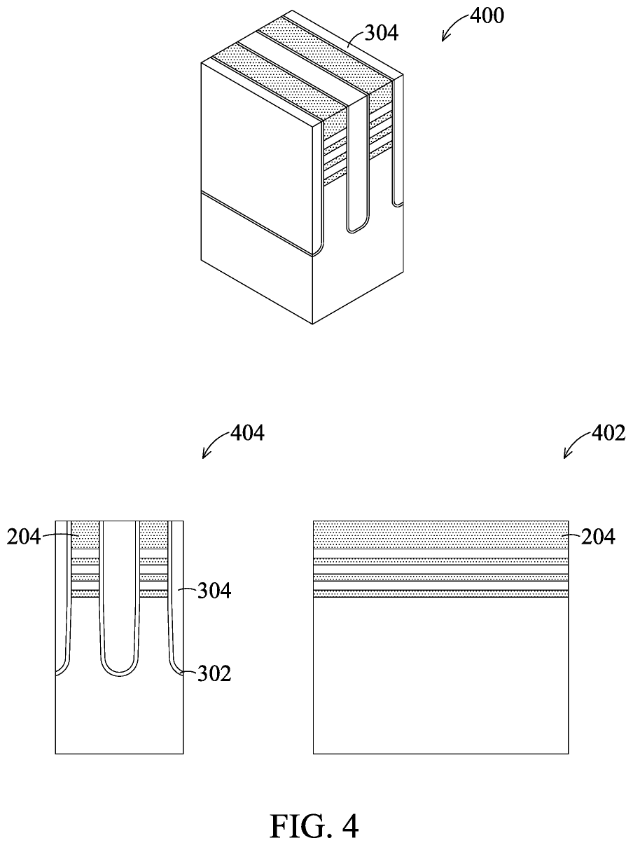

Corresponding to operation 106 of FIG. 1, FIG. 4 shows a perspective view 400 and cross-sectional views 402 and 404 of the stack of layers following a CMP process and an etching process. As shown, the etching process has removed the hardmask 206 shown in FIGS. 2-3, and the CMP and etching process has made the top-most layer of the sacrificial material 204 level with the second dielectric material 304 described in connection with FIG. 3. The cross-sectional view 404 shows the first dielectric material 302 is also exposed at the top of the device following the CMP process. Any type of suitable CMP process or etching process can be used to remove the top layers of the hardmask 206, the first dielectric material 302, and the second dielectric material 304, including dry or wet etching techniques. The etching techniques may be implemented using the sacrificial material 204 as an etch-stop layer.

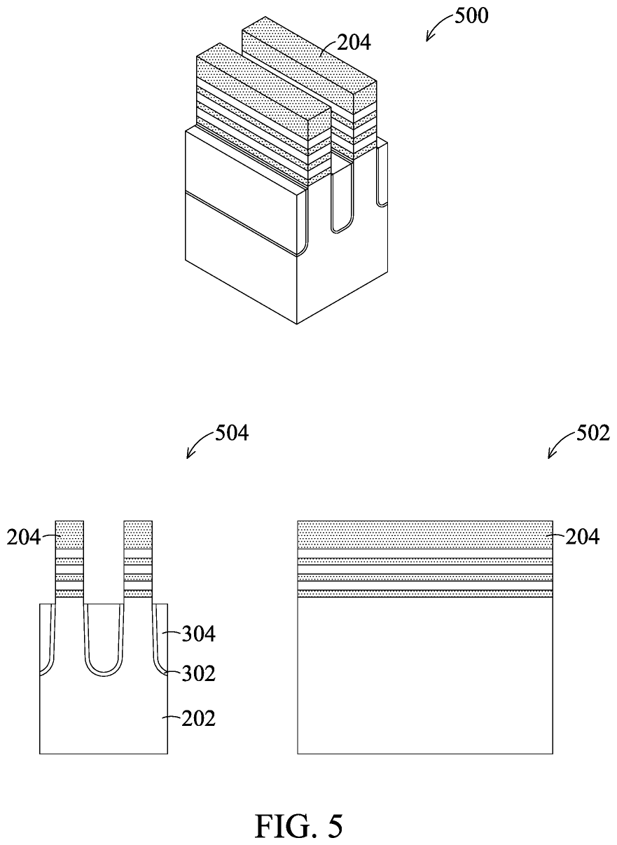

Still corresponding to operation 106 of FIG. 1, FIG. 5 shows a perspective view 500 and cross-sectional views 502 and 504 of the stack of layers following an etching process to remove portions of the first dielectric material 302 and the second dielectric material 304. As shown, the selective etching process is selective to the first dielectric material 302 and the second dielectric material 304, and does not remove the sacrificial material 204 or the substrate material 202. The etching process can be performed until the lower-most layer of the sacrificial material 204 is exposed, along with a small portion of the substrate material 202 below the lower-most layer of the sacrificial material 204. Any type of suitable etchant or material removal process may be used that is selective to the second dielectric material 304 and/or the first dielectric material 302. In some embodiments, two etching steps may be performed, one that is selective to the second dielectric material 304, and a second that is selective to the first dielectric material 302.

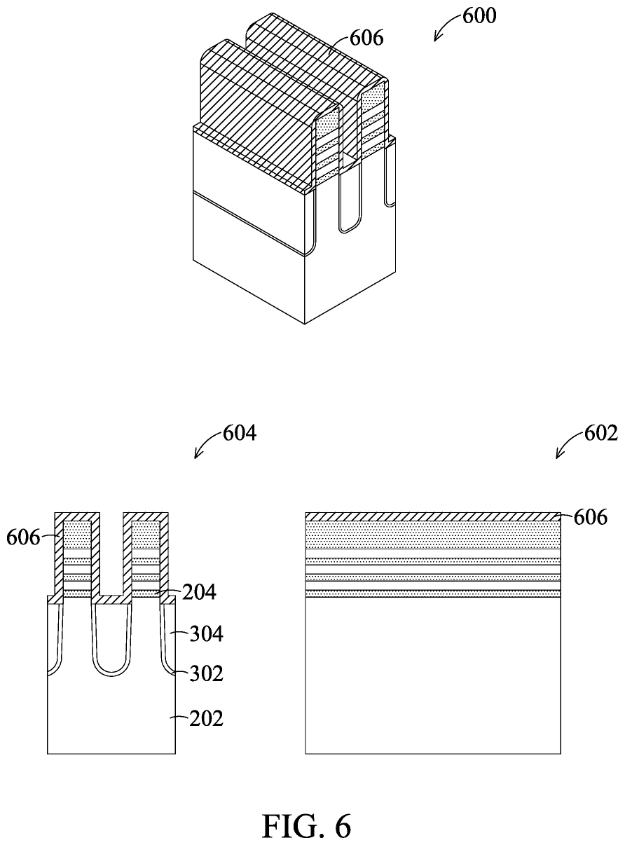

Corresponding to operation 108 of FIG. 1, FIG. 6 shows a perspective view 600 and cross-sectional views 602 and 604 of the stack of layers following deposition of a second sacrificial material 606. The second sacrificial material 606 may be any type of suitable that may be deposited or epitaxially grown on the substrate material 202 or the sacrificial material 204. In some embodiments, the second sacrificial material 606 may be the same material as the sacrificial material 204, or may be a different material. The second sacrificial material 606 can be a semiconductor alloy material, such as SiGe or another suitable sacrificial material. The second sacrificial material 606 can be formed to encapsulate the top of the device, as shown in the perspective view 600 and the cross-sectional view 604. The sacrificial material 606 may be formed as a cladding layer over the device.

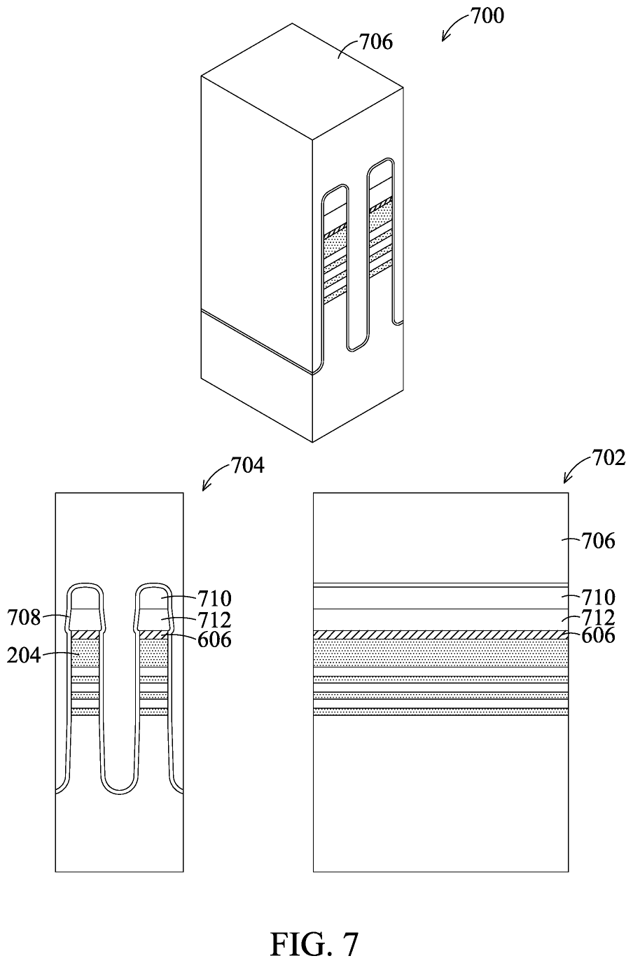

Corresponding to operation 110 of FIG. 1, FIG. 7 shows a perspective view 700 and cross-sectional views 702 and 704 of the stack of layers following formation of a first hardmask 712, a second hardmask 710, a liner material 708, and a third dielectric material 706. The liner material 708 can first be formed to cover the second sacrificial material 606, which is formed as a cladding layer. The liner material 708 can be deposited as a thin interface between the second sacrificial material 606 and the third dielectric material 706. The liner material 708 can be formed using any suitable material deposition process, and may include materials such as SiCN. After depositing the liner material 708, a first hardmask 712 can be formed on liner material 708 over the top layer of the sacrificial material 204. The first hardmask 712 can be any suitable hardmask material, such as SiN, and can be patterned and formed using any suitable material deposition technique. The second hardmask 710 can be patterned or selectively deposited on top of the first hardmask 712. The second hardmask 710 may be a different material than the first hardmask 712, such as an oxide material (e.g., SiOx). After forming the first hardmask 712 and the second hardmask 710, an additional layer of the liner material 708 can be formed using similar techniques to those described above. Next, a third dielectric material 706 can be formed on top of the liner material 708. The third dielectric material 706 can be formed using techniques similar to those used to form the second dielectric material 304 described in connection with FIG. 3. In some embodiments, the third dielectric material 706 can be the same material as the second dielectric material 304.

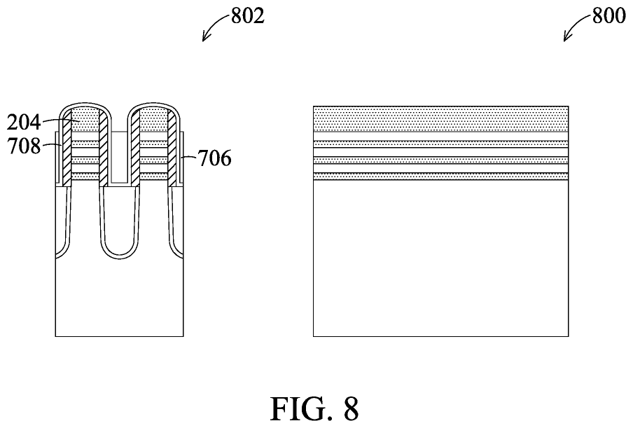

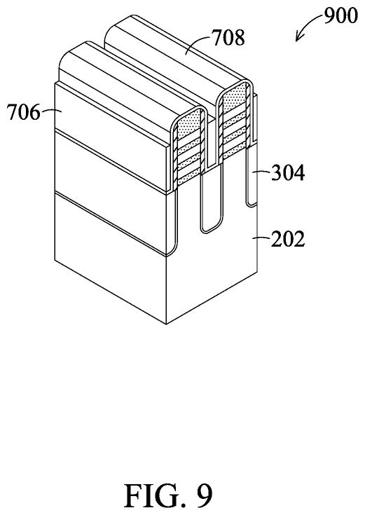

Corresponding to operation 112 of FIG. 1, FIG. 8 shows a cross-sectional views 800 and 802 of the stack of layers following an etching process that removes the first hardmask 712, the second hardmask 710, and the third dielectric material 706. FIG. 9 shows a perspective view 900 of the stack of layers following the same etching process. As shown in the cross-sectional view 800, the first hardmask 712 and the second hardmask 710 have been removed, along with the upper portion of the third dielectric material 706. This exposes an upper portion of the liner material 708. Any suitable etching processes, including dry or wet etching processes, can be used to remove the aforementioned materials. As shown in the cross-sectional view 802, the third dielectric material 706 can be etched until it is above level with the bottom of the top layer of the sacrificial material 204.

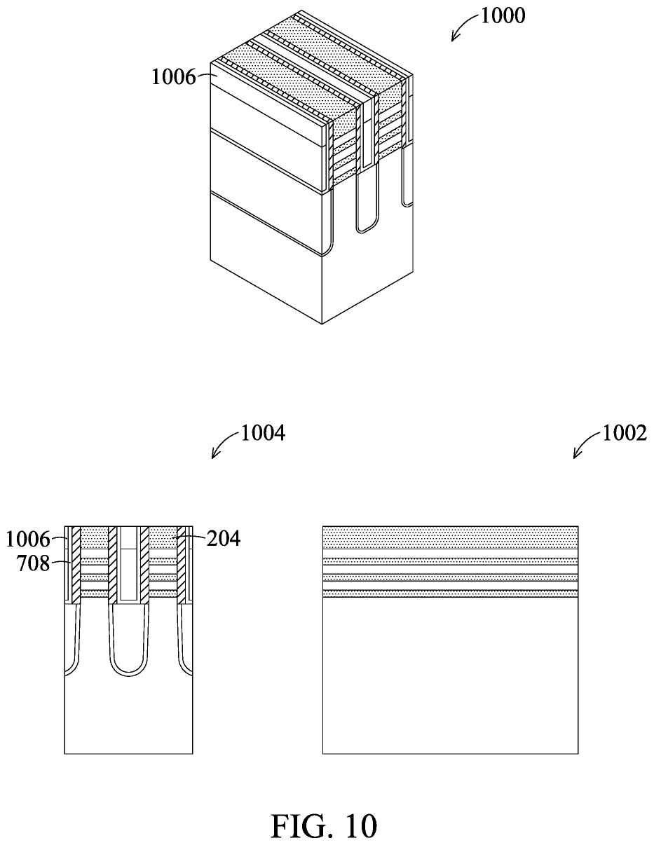

Corresponding to operation 114 of FIG. 1, FIG. 10 shows a perspective view 1000 and cross-sectional views 1002 and 1004 of the stack of layers following formation of a high-k dielectric material 1006. The high-k dielectric material 1006 can be an insulating material with a relative large dielectric constant, k. The high-k dielectric material 1006 may include oxide materials or other insulating materials. The high-k dielectric material 1006 can be formed using any suitable material deposition technique, such as chemical vapor deposition (CVD), physical vapor deposition (PVD), ALD, or other suitable processes. After forming the high-k dielectric material 1006, a CMP process can be performed to planarize the device. This can also remove an upper portion of the liner material 708, and expose the upper layer of the sacrificial material 204. As shown, the sacrificial material 204 is level with the high-k dielectric material 1006 following the CMP process.

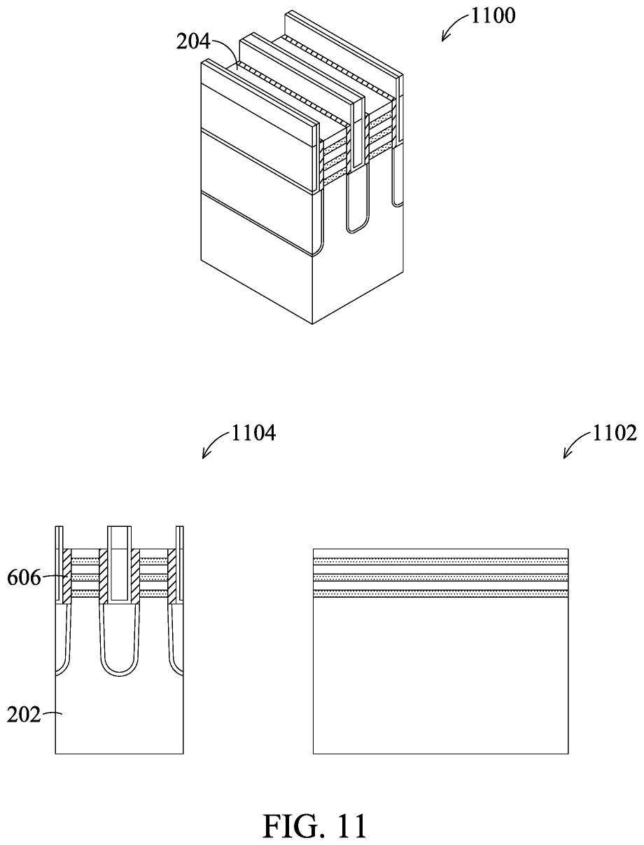

Corresponding to operation 116 of FIG. 1, FIG. 11 shows a perspective view 1100 and cross-sectional views 1102 and 1104 of the stack of layers following a selective etching process. As shown in the perspective view 1100 and the cross-sectional view 1104, the etching process can remove the top layer of the sacrificial material 204. The perspective view 1100 shows a very thin layer of the sacrificial material 204 remains on top of the substrate material 202. Additionally, the etching process can remove an upper portion of the second sacrificial material 606. The etching process used may be selective to both the sacrificial material 204 and the second sacrificial material 606. In some embodiments, multiple selective etching processes may be used to remove the upper portions of the sacrificial material 204 and the second sacrificial material 606. As shown, the second sacrificial material 606 can be etched until level with the top layer of the substrate material 202.

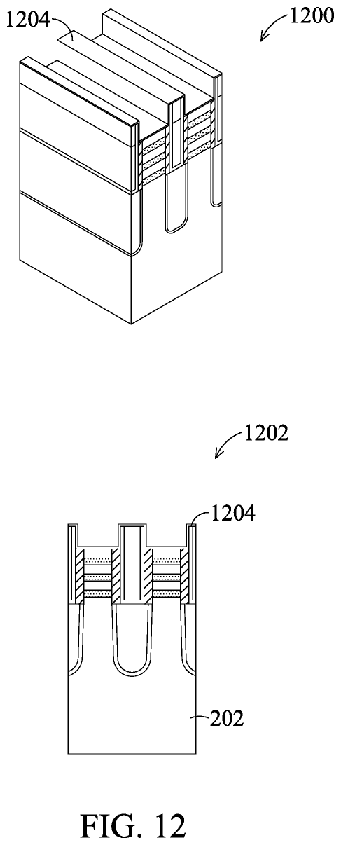

Corresponding to operation 118 of FIG. 1, FIG. 12 shows a perspective view 1200 and a cross-sectional views 1202 of the stack of layers following the deposition of a fourth dielectric material 1204. The fourth dielectric material 1204 can be formed as a thin layer over the top of the device. The fourth dielectric material 1204 can be any type of suitable insulating material, such as an oxide material. The fourth dielectric material 1204 can be formed using any type of suitable material deposition technique, such as CVD, PVD, ALD, or other suitable processes. The fourth dielectric material 1204 can electrically isolate the substrate material 202 from additional material layers added in future process steps. As shown in the perspective view 1200, the fourth dielectric material 1204 can cover the entirety of the top of the device.

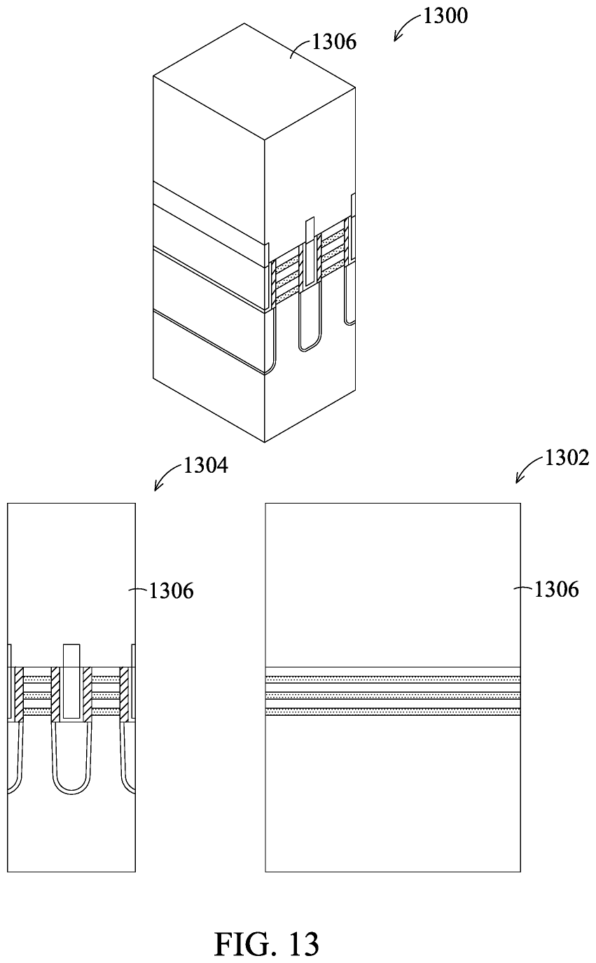

Corresponding to operation 120 of FIG. 1, FIG. 13 shows a perspective view 1300 and cross-sectional views 1302 and 1304 of the stack of layers following the deposition of a PO material 1306. As shown, the PO material 1306 (e.g., sometimes referred to as a first gate material or structure) covers the entirety of the device, and is deposited on the fourth dielectric material 1204 described in connection with FIG. 12. The PO material 1306 can be, for example, a polysilicon material. The PO material 1306 can be used as a placeholder region, which will be removed in layer process steps to form metal gate materials. The PO material 1306 can be deposited using any suitable material deposition technique, including ALD, CVD, PVD, among other techniques. PO material 1306 can be deposited to a predetermined thickness, according to design parameters of the device.

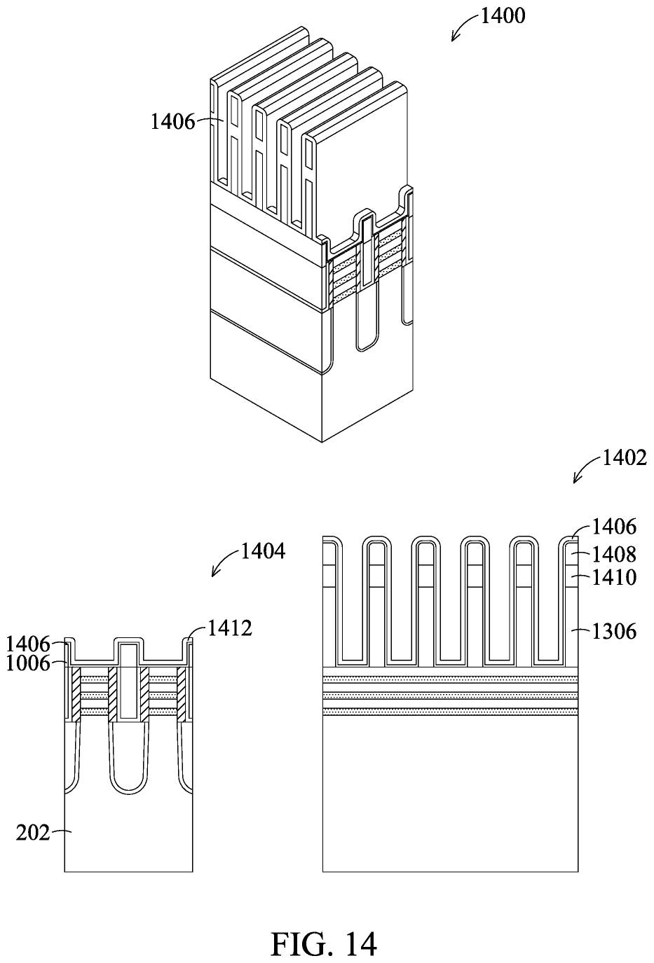

Corresponding to operation 122 of FIG. 1, FIG. 14 shows a perspective view 1400 and cross-sectional views 1402 and 1404 of the stack of layers following the patterning and etching the of the PO material 1306. To etch the PO material 1306, a third hardmask 1410 and a fourth hardmask 1408 can first be patterned on top of the PO material 1306. The third hardmask 1410 and the fourth hardmask 1408 can be patterned, for example, using a photo resist material, such that the third hardmask 1410 and the fourth hardmask 1408 form strips that are perpendicular to the fin structures formed from the sacrificial material 204 and the substrate material 202. The third hardmask 1410 and the fourth hardmask 1408 can be similar to the first hardmask 712 and the second hardmask 710 described in connection with FIG. 7, and can be made from similar materials and formed using similar techniques. After depositing the third hardmask 1410 and the fourth hardmask 1408, the PO material 1306 can be selectively and vertically etched, such that the PO material 1306 below the third hardmask 1410 and the fourth hardmask 1408 are not removed by the etching process. Any suitable vertical etching process or material removal process can be used.

After etching the PO material 1306, a layer of a second liner material 1412 can be deposited over the top of the device, covering the PO material 1306, the third hardmask 1410 and the fourth hardmask 1408, the substrate material 202, and the high-k dielectric material 1006. The second liner material 1412 can be similar to the liner material 708 described in connection with FIG. 7. The second liner material 1412 can be any type of suitable insulating material, such as an oxide or another type of insulator. After depositing the second liner material 1412, a layer of a spacer material 1406 is deposited over the device. As shown, the layer of the spacer material evenly covers all materials on the surface of the device. The spacer material 1406 can be deposited using any suitable material deposition technique, such as ALD, CVD, PVD, among others. The spacer material can be used to protect materials on the device from etching processes in further process steps.

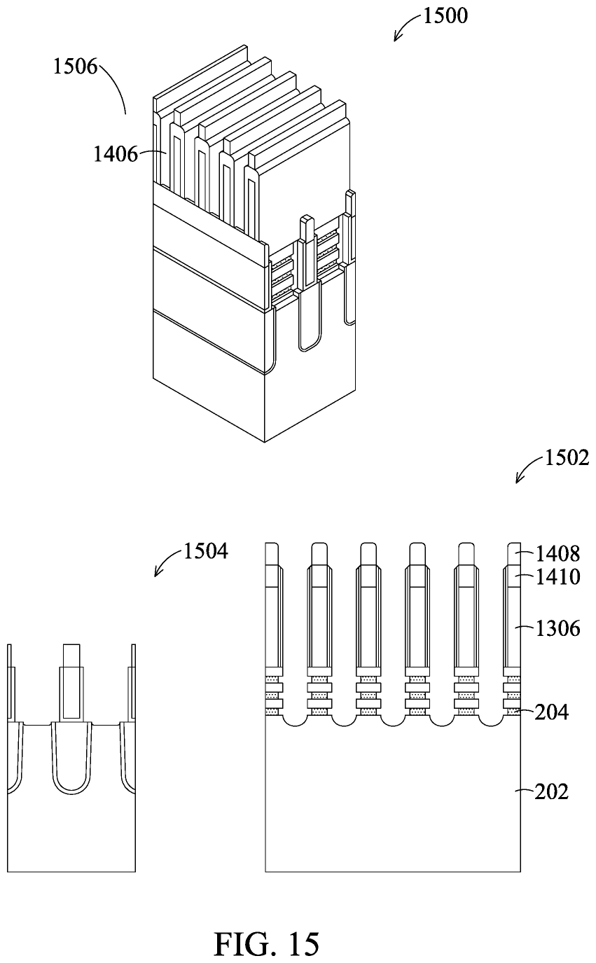

Corresponding to operation 124 of FIG. 1, FIG. 15 shows a perspective view 1500 and cross-sectional views 1502 and 1504 of the stack of layers following a vertical etching process. As shown, the materials added in the previous process step are vertically etched to create a number of troughs in the substrate material 202 between the PO material 1306 structures. The vertically etching process can be performed to etch the substrate to below the bottom-most layer of the sacrificial material 204. As shown in the cross-sectional view 1502, the troughs are formed through the alternating layers of the substrate material 202 and the sacrificial material 204. The etching process causes the layers of the sacrificial material 204 to be recessed relative to the sides of the troughs. The third hardmask 1410, the fourth hardmask 1408, and the spacer material 1406 protect the PO material 1306 from the etching process, such that it remains intact following the etching process and defines the walls of each trough. Although some of the layers of the sacrificial material 204 are etched, portions of the sacrificial material 204 remain under each PO material 1306 structure.

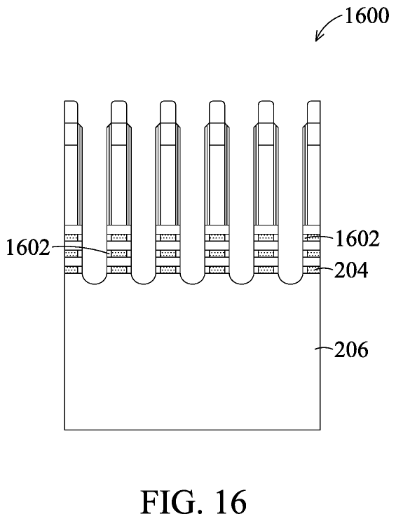

Corresponding to operation 126 of FIG. 1, FIG. 16 shows a cross-sectional view 1600 of the stack of layers after forming spacers 1602 on the sacrificial material 204. As described above, the prior etching process caused the layers of the sacrificial material 204 making up portions of the walls of the troughs in the substrate material 202 to become recessed slightly. The spacers 1602 can be formed in air gaps between the layers of the substrate material 202, which were created when recessing the sacrificial material 204. The spacers 1602 can be formed from any type of suitable insulating material with a relatively low dielectric constant k, such as silicon oxide, silicon oxycarbonitride (SiOCN), or the like. Any suitable deposition method, such as thermal oxidation, CVD, or the like, may be used to form the spacers 1602. The shapes and formation methods of the spacers 1602 as illustrated in FIG. 16 are merely non-limiting examples, and other shapes and formation methods are possible. These and other variations are fully intended to be included within the scope of the present disclosure.

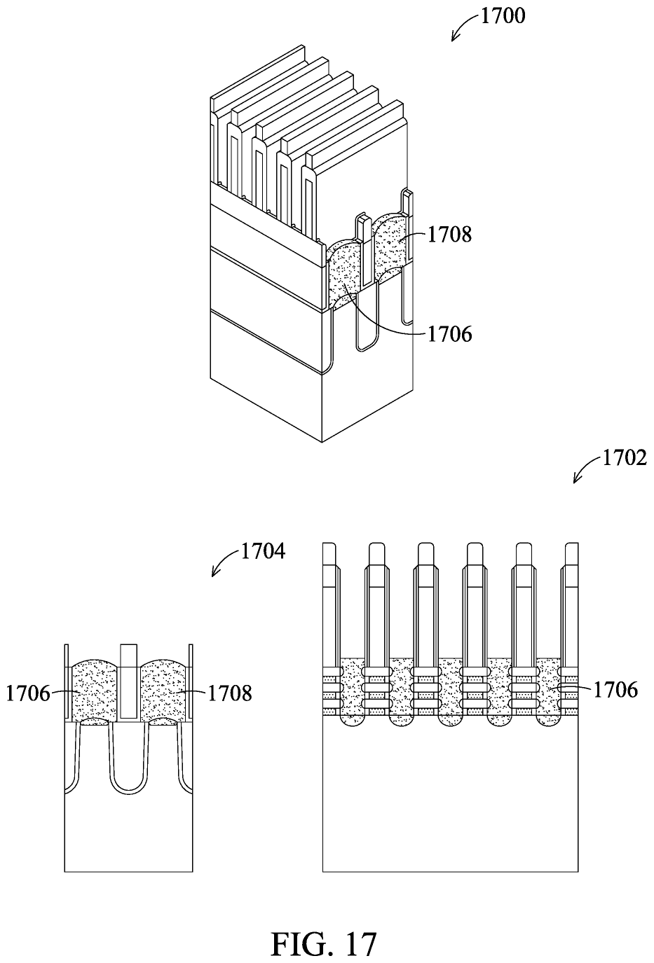

Corresponding to operation 128 of FIG. 1, FIG. 17 shows a perspective view 1700 and cross-sectional views 1702 and 1704 of the stack of layers following epitaxial growth of a first doped semiconductor material 1706 and a second doped semiconductor material 1708. Each of the first doped semiconductor material 1706 and the second doped semiconductor material 1708 can be epitaxially grown using the substrate 202 as a seed material in the troughs formed in previous etching steps. To form each of first doped semiconductor material 1706 and the second doped semiconductor material 1708, selective patterning may be performed to guide the epitaxial growth of the first doped semiconductor material 1706 and the second doped semiconductor material 1708 in respective regions of each trough. For example, a dielectric material (not shown) or other masking material may be used to prevent epitaxial growth on some regions of the substrate material 202, allowing for selective growth of both P-type and N-type semiconductive material.

The first doped semiconductor material 1706 and the second doped semiconductor material 1708 may be doped to have the same or a different polarity. The first doped semiconductor material 1706 and the second doped semiconductor material 1708 may have an impurity (e.g., dopant) concentration in a range from about 1×10¹⁹ cm⁻³ to about 1×10²¹ cm⁻³. P-type impurities, such as boron or indium, or N-type impurities, such as phosphorous or arsenide, may be implanted in the first doped semiconductor material 1706 or the second doped semiconductor material 1708. In some embodiments, the first doped semiconductor material 1706 and the second doped semiconductor material 1708 may be in situ doped during their growth.

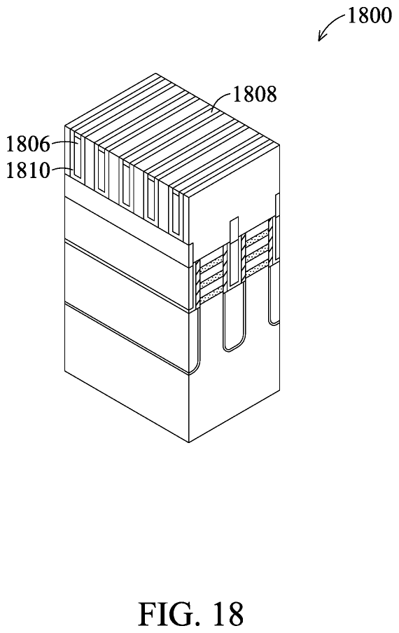

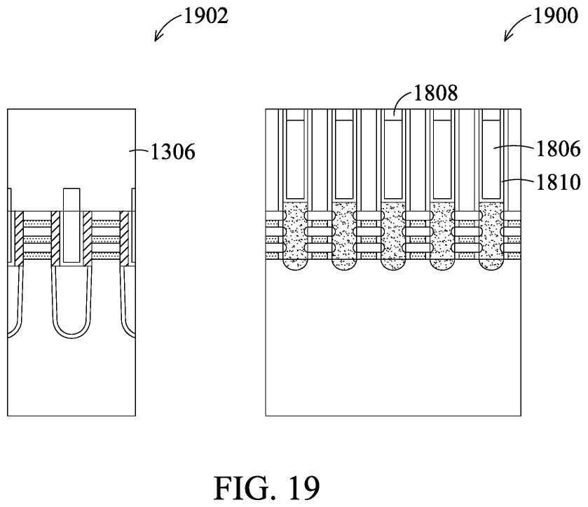

Corresponding to operation 130 of FIG. 1, FIGS. 18 and 19 show a perspective view 1800 and cross-sectional views 1900 and 1902 of the stack of layers following the deposition of a CESL material 1810, an ILD material 1806, and a dielectric layer 1808. First, a CESL material 1810 is formed over the first doped semiconductor material 1706 and the second doped semiconductor material 1708. The CESL material 1810 can function as an etch stop layer in a subsequent etching process, and may comprise a suitable material such as silicon oxide, silicon nitride, silicon oxynitride, combinations thereof, or the like, and may be formed by a suitable formation method such as CVD, PVD, combinations thereof, or the like.

Next, the ILD material 1806 is formed over the CESL material 1810. In some embodiments, the ILD material 1806 is formed of a dielectric material such as silicon oxide, phosphosilicate glass (PSG), borosilicate glass (BSG), boron-doped phosphosilicate Glass (BPSG), undoped silicate glass (USG), or the like, and may be deposited by any suitable method, such as CVD, PECVD, or FCVD. After the ILD material 1806 is formed, an optional dielectric layer 1808 is formed over the ILD material 1806. The dielectric layer 1808 can function as a protection layer to prevent or reduces the loss of the ILD material 1806 in subsequent etching processes. The dielectric layer 1808 may be formed of a suitable material, such as silicon nitride, silicon carbonitride, or the like, using a suitable method such as CVD, PECVD, or FCVD. After the dielectric layer 1808 is formed, a planarization process, such as a CMP process, may be performed to achieve a level upper surface for the dielectric layer. The CMP may also remove the third hardmask 1410 and the fourth hardmask 1408 and portions of the CESL material 1810. After the planarization process, the upper surface of the dielectric layer 1808 is level with the upper surface of the PO material 1306, in some embodiments.

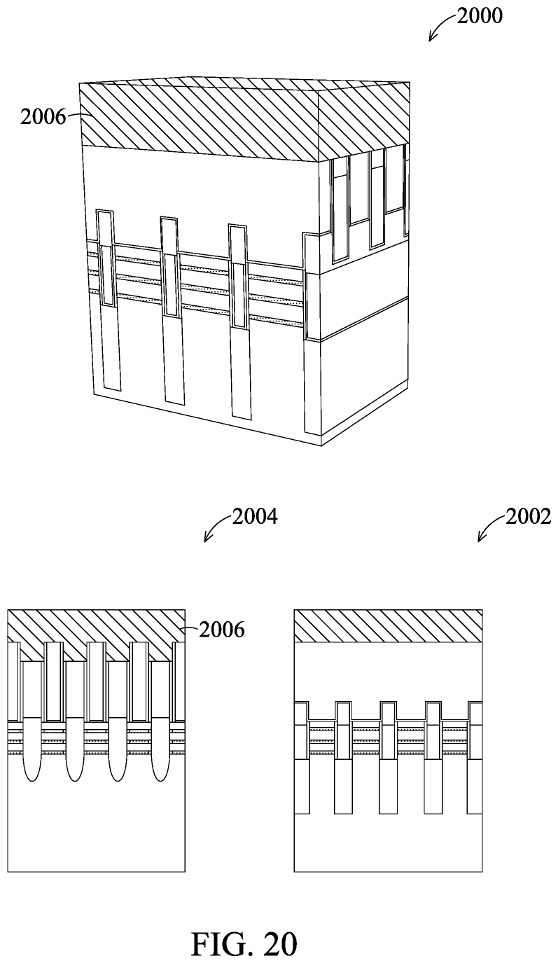

Corresponding to operation 132 of FIG. 1, FIG. 20 shows a perspective view 2000 and cross-sectional views 2002 and 2004 of the stack of layers at the start of a CPODE process. At the start of the CPODE process, a hardmask layer 2006 can be deposited over the surface of the device. The hardmask layer 2006 can be any type of suitable dielectric material, including as silicon nitride, silicon carbonitride, or the like, and may be formed using a suitable method such as CVD, PECVD, or FCVD. After the hardmask layer 2006 is formed, a planarization process, such as a CMP process, may be performed.

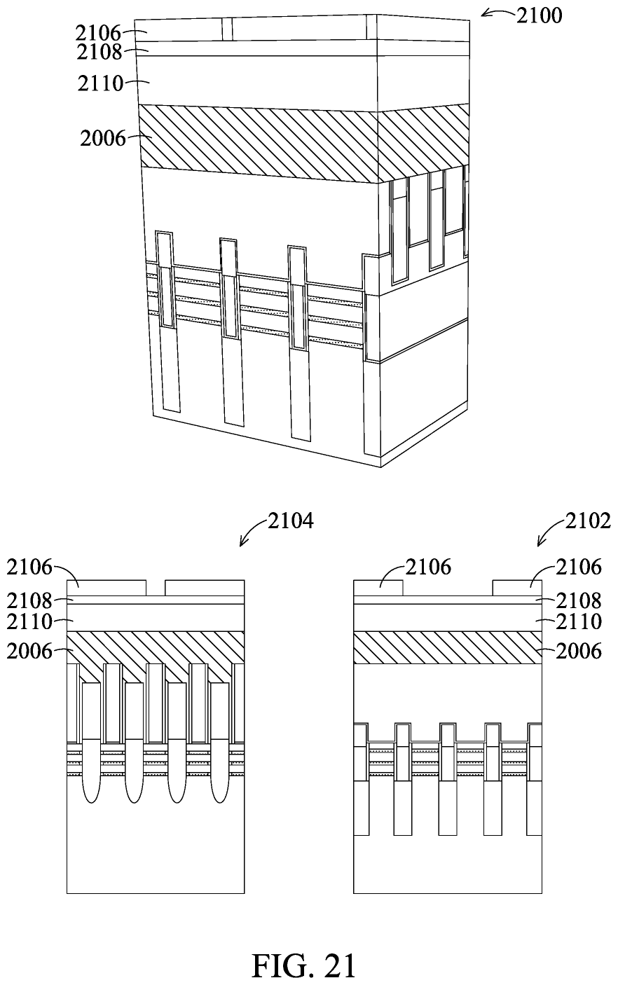

Still corresponding to operation 132 of FIG. 1, FIG. 21 shows a perspective view 2100 and cross-sectional views 2102 and 2104 of the stack of layers undergoing a CPODE process. As shown, a second hardmask layer 2110 and a third hardmask layer 2108 are formed on top of the hardmask layer 2006, followed by a layer of patterned photoresist 2106. As shown, the patterned photoresist includes a slot-shaped opening, which is positioned to guide further etching processes. To pattern the photoresist 2106, the photoresist 2106 is deposited, irradiated (exposed), and developed to remove predetermined portions of the photoresist 2106. The remaining photoresist 2106 protects the underlying layers from subsequent processing steps, such as etching.

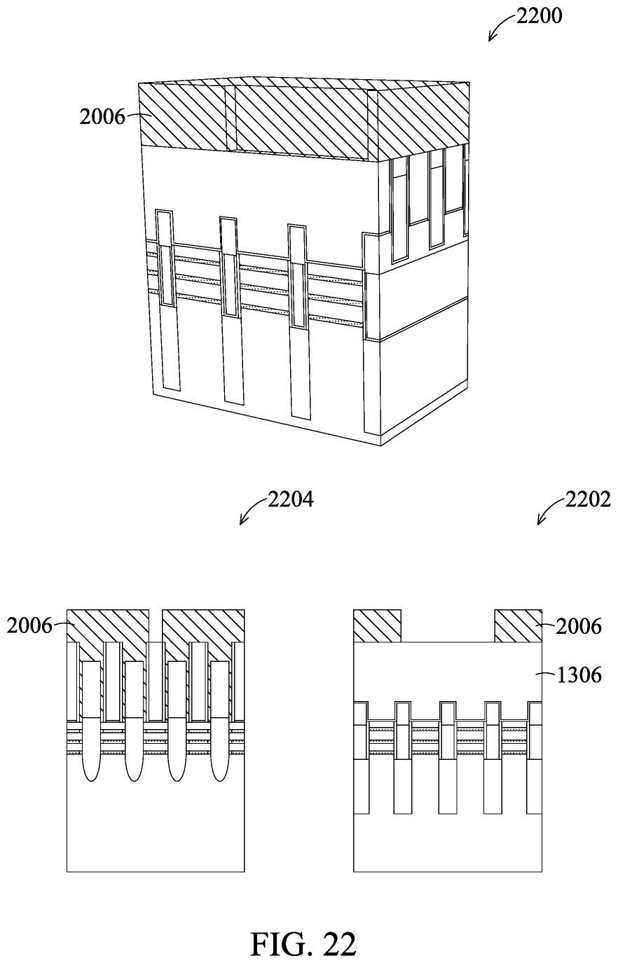

Corresponding to operation 134 of FIG. 1, FIG. 22 shows a perspective view 2200 and cross-sectional views 2202 and 2204 of the stack of layers undergoing the CPODE process to isolate one or more transistor structures that will be formed in the stack of layers. As shown, using suitable etching processes, each of the photoresist 2106, the second hardmask layer 2110, and the third hardmask layer 2108 have been removed, along with a slot-shaped portion of the hardmask 2006. As shown, the slot-shaped portion that is removed from the hardmask 2006 was previously defined by the corresponding opening in the photoresist 2106. The etching process can be a vertical etching process towards the PO material 1306, with the PO material 1306 serving as an etch stop layer.

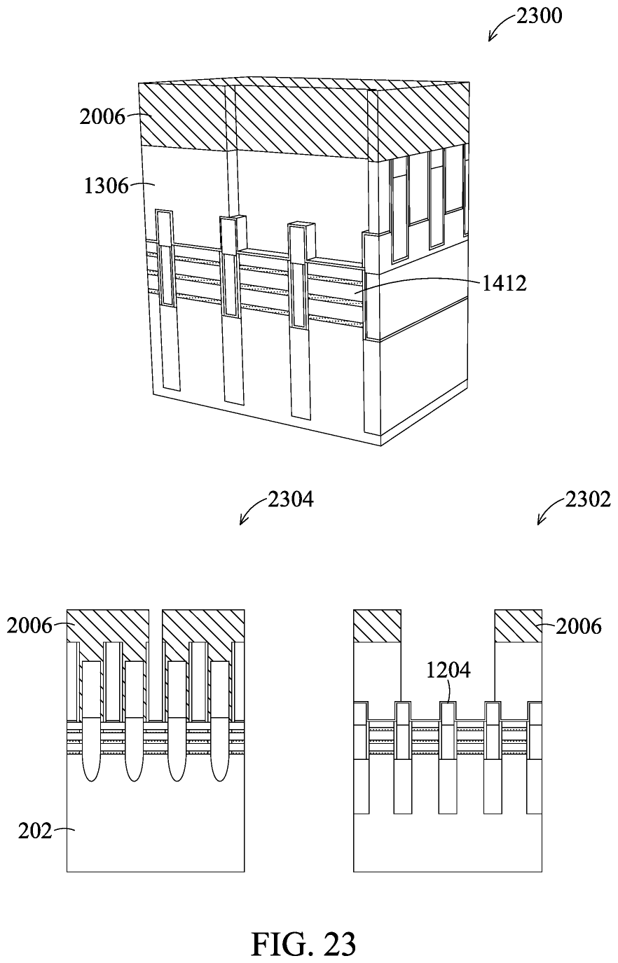

Still corresponding to operation 134 of FIG. 1, FIG. 23 shows a perspective view 2300 and cross-sectional views 2302 and 2304 of the stack of layers undergoing the CPODE process. As shown, an additional vertical etching process in the direction towards the substrate 202 is performed to remove a portion of the PO material 1306 (e.g., at least a part of a first etching process). Any suitable etching process, such as a dry etching process or a wet etching process, can be used to remove the PO material 1306. For instance, the etching process can involve at least one of transformer coupled plasma (TCP) or inductively coupled plasma (ICP) etching technique(s) for directionally removing the PO material 1306. The fourth dielectric material 1204 can act as an etch-stop for the etching process. The etching process can be directional, such that the PO material 1306 is removed in the predetermined slot-shape defined by the hardmask layer 2006.

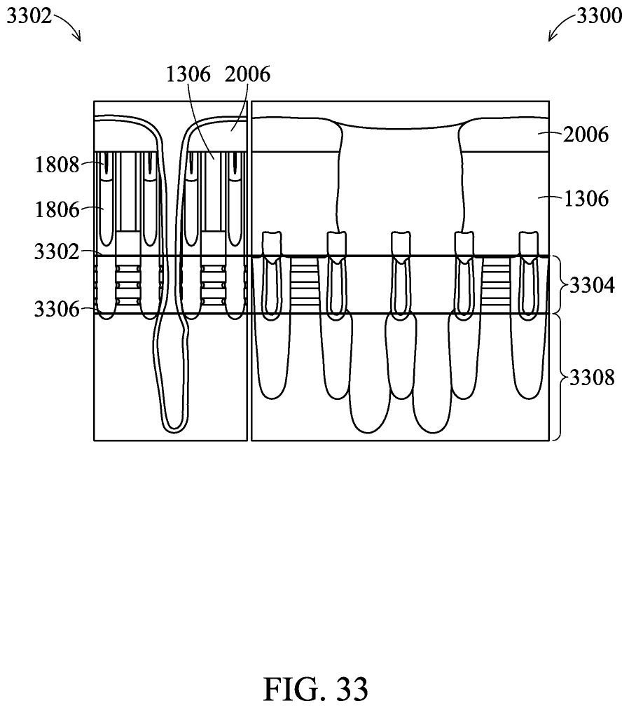

For example, to perform the etching process, particular etching conditions can be utilized to minimize or avoid bowing or contorting the side surface(s) of the PO material 1306 and to achieve the results described herein. As the vertical etch is performed from the top of the device towards the bottom, the etching process begins by etching through the hardmask 2006 and the PO material 1306. As described in conjunction with FIG. 33, prior to the boundary 3302, any suitable etching technique can be used to remove the PO material 1306. For example, the CPODE etching process can include or involve directional etching of the PO material 1306 to control the bowing, such as by configuring at least one of oxygen (O₂) flush time (or rate), argon (Ar) sputter time (or rate), and/or the cycle of at least one of SiCl₄, nitrogen gas (N₂), O₂, and/or chlorine, silane (SiH₄), among others. For instance, the gas used in the etching process of the PO material 1306 can involve using an O₂ flush of 100-200 standard cubic centimeter per minute (sccm), Ar sputter including carbon tetrafluoride (CF₄) of 0-100 about sccm and Ar of about 500-1000 sccm, the cycle including SiCl₄ of about 0-50 sccm, N₂ of about 0-100 sccm, O₂ of about 0-100 sccm, and Cl₂ of about 100-500 sccm, etc. Hence, as shown in the before and after comparison, utilizing the etching process can minimize or control the bowing of the PO material 1306, providing a comparatively vertical or linear side surface of the PO material 1306. This can prevent any unintended short-circuits, current leakage, or logic circuits that do not function properly.

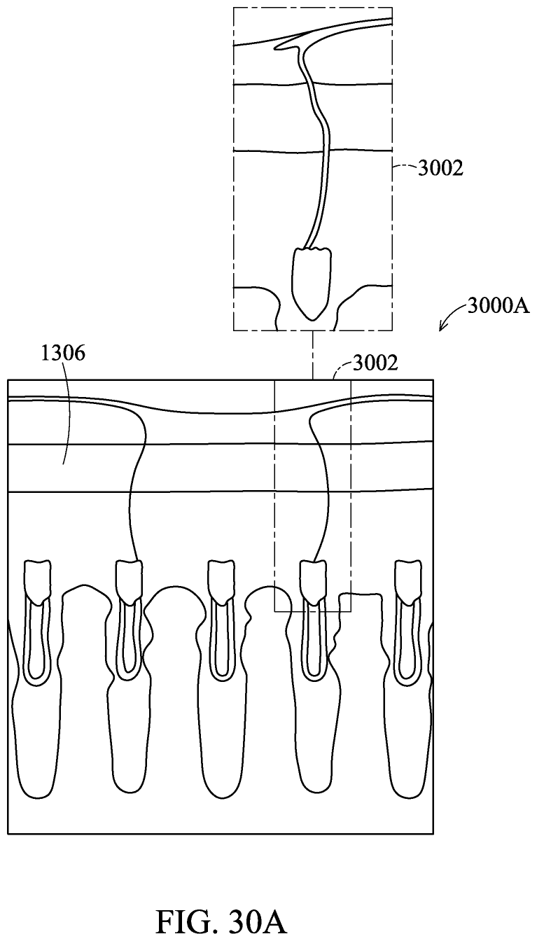

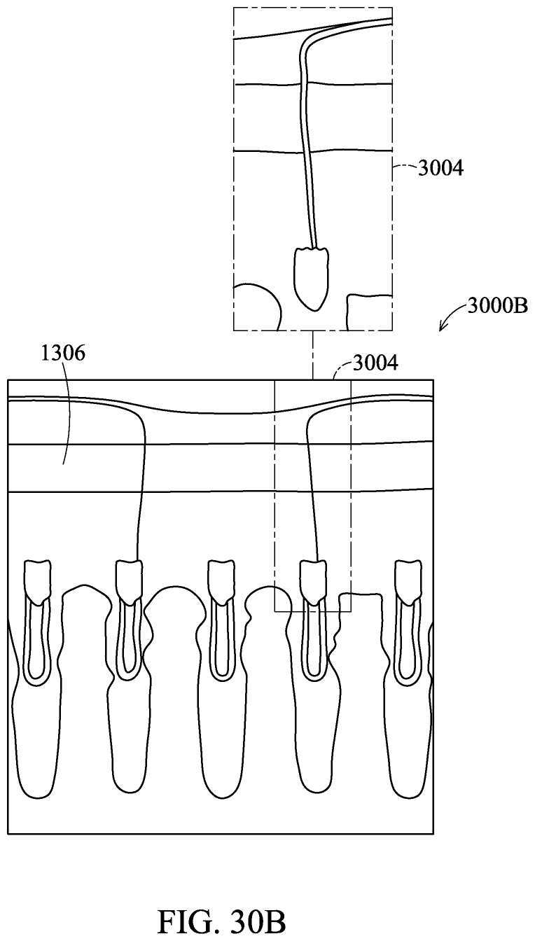

Further to operation 134 of FIG. 1, a before and after comparison of an etching process that does not utilize the particular etching techniques described herein are shown in FIGS. 30A and 30B, respectively. As shown, FIG. 30A shows a cross-sectional photograph 3000A of transistor devices that do not utilize the particular etching techniques described herein. FIG. 30B shows a cross-sectional photograph 3000B of the transistor devices that utilize the etching techniques described herein. For example, the PO material 1306 can be etched using at least one of the etching processes. However, as shown in portion 3002 of the cross-sectional photograph 3000A, without utilizing the etching processes described herein, bowing or curvature may be introduced at the side surfaces of the PO material 1306 (e.g., bowing of the opening to expose the surface of at least one of the fourth dielectric material 1204, the stack of layers, among other structures or materials, such as shown in conjunction with FIG. 23). As shown, following the etching process described herein, the curvature or bowing of the PO material 1306 during the etching process can be avoided or controlled (e.g., as shown in portion 3004 of the cross-sectional photograph 3000B).

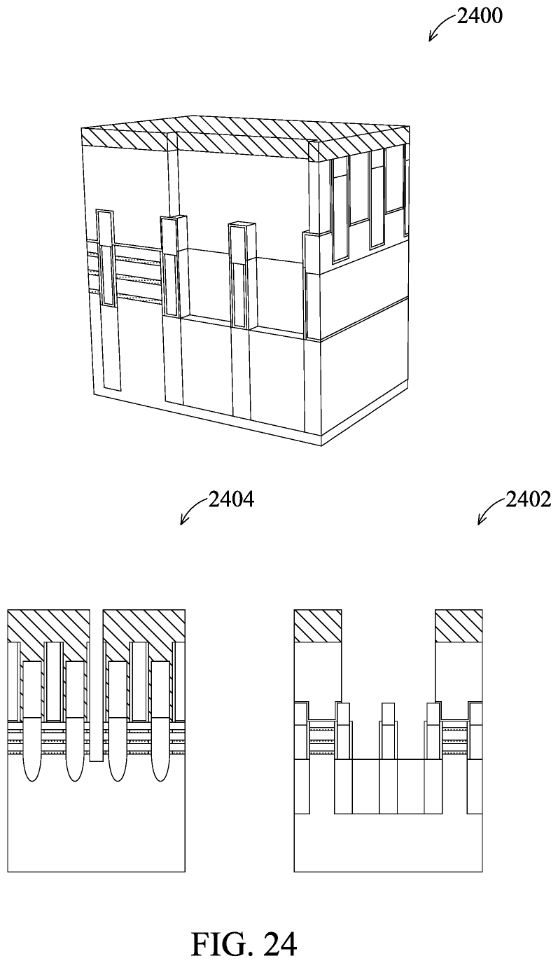

Corresponding to operation 136 of FIG. 1, FIG. 24 shows a perspective view 2400 and cross-sectional views 2402 and 2404 of the stack of layers undergoing the CPODE process. At this stage in the CPODE process, one or more directional etching processes (e.g., at least a part of a second etching process) are utilized to remove at least one portion of the stack of layers, such as the fourth dielectric material layer 1204, one or more layers of the substrate 202, and one or more layers of the sacrificial material 204 that are positioned beneath the slot defined by the hardmask layer 2006. In some cases, the layers of substrate 202 and the one or more layers of the sacrificial material 204 can correspond to or be a part of a channel region of various channel regions of the stack of layers (e.g., each extending in a first lateral direction and includes a respective pair of epitaxial structures). In some cases, the layers of substrate 202 (e.g., semiconductor layers) can be vertically spaced from one another by at least one of the spacer 1602 or the sacrificial material 204, for example. The layers of substrate 202 can be in contact with a corresponding pair of epitaxial structures (e.g., the doped semiconductor material 1706). To remove a portion of one or more channel regions, particular etching processes can be utilized to minimize the loss of STI (e.g., including the third dielectric material 706 and/or the liner material 708) or reduce recessing of the STI (e.g., less than 10 nm STI recess). In various implementations, the channel regions can include respective lower portions. The adjacent ones of the lower portions may be separated from each other with a corresponding one of various isolation structures (e.g., the second dielectric material 304, or other related materials between the adjacent lower portions of the channel regions).

For example, to perform the etching process, particular etching conditions can be utilized to minimize STI loss and to achieve the results described herein. When the etching process (e.g., the etching process described in conjunction with FIG. 33) reaches the boundary 3302, a low-selective etching process can be used to break through the fourth dielectric material layer 1204 (shown in FIG. 23). The gas used in the etching process can involve using 0 to 200 about sccm of carbon tetrafluoride (CF₄), and 100 to 1000 about sccm of argon (Ar) gas. Once the oxide layer has been etched, the direction etching process can continue in the region 3304 (e.g., including or associated with one or more channel regions). In this region, a highly selecting etching process of the substrate 202 to the spacers 1602 can be performed, in addition to SiO deposition process. The substrate etching process can utilize about 100 to about 1000 sccm of hydrogen bromide (HBr), about 0 to about 100 sccm of oxygen (O₂), and about 100 to about 1000 sccm of argon (Ar).

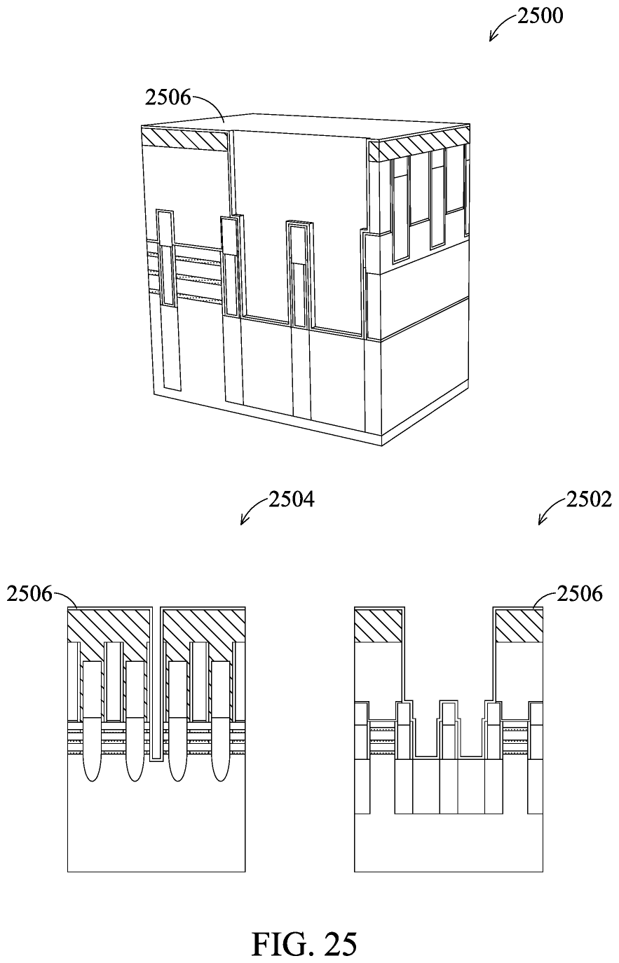

Corresponding to operation 138 of FIG. 1, FIG. 25 shows a perspective view 2500 and cross-sectional views 2502 and 2504 of the stack of layers following the deposition of at least one protection layer. After removing at least a portion of the channel region including one or more layers of the substrate 202 and one or more layers of the sacrificial material 204, the SiO deposition process can be performed to deposit at least one dielectric layer 2506. In some embodiments, a number of such SiO deposition processes (sometimes referred to as cycles) can be performed. The dielectric layer 2506 can be composed of any suitable dielectric material. The dielectric layer 2506 can correspond to or be referred to as a protection layer, such as to protect the epitaxially grown semiconductor materials or structures. The dielectric layer 2506 can cover the exposed surface of the stack of layers, such as shown in FIG. 25. The SiO deposition process can involve a deposition process and an oxidization process. For example, the deposition process can be performed using about 0 to about 100 sccm of SiCl₄, about 100 to about 500 sccm of HBr, and about 100 to about 1000 sccm of Ar. The oxidization process can be performed with about 10 to about 200 sccm of O₂.

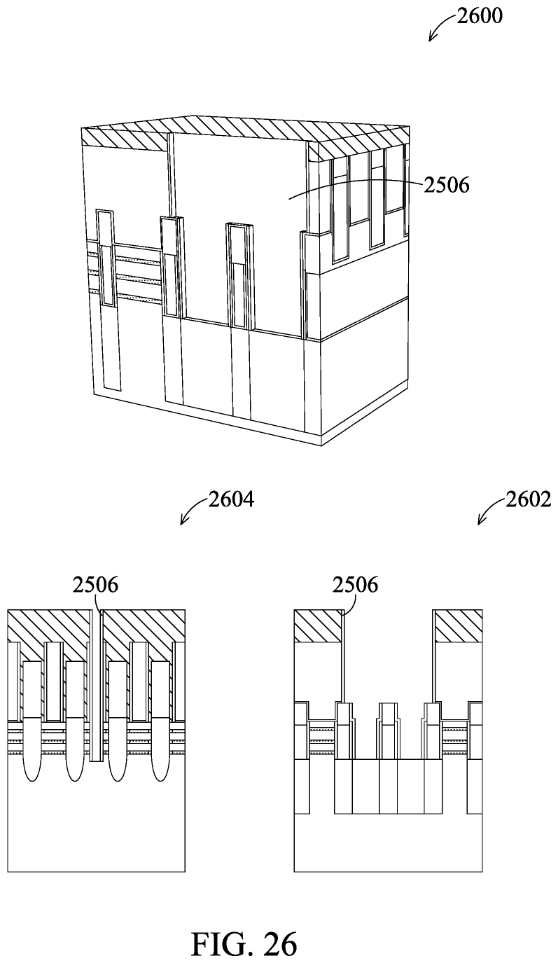

Corresponding to operation 140 of FIG. 1, FIG. 26 shows a perspective view 2600 and cross-sectional views 2602 and 2604 of the stack of layers undergoing the CPODE process. After the SiO deposition process, a portion of the dielectric layer 2506 can be etched using a suitable etching technique. For example, a low-selective etching process can be used to break through the dielectric layer 2506 (e.g., protection layer). The gas used in the etching process can involve using about 0 to about 200 sccm of CF₄, and about 100 to about 1000 sccm of Ar gas. As shown or described in conjunction with FIG. 33, the low-selective etching process can remove the portion of the dielectric layer 2506 at boundary 3306. Once the low-selective etching process is performed, the top surface of hardmask layer 2006 and at least a portion of the surface of the substrate 202 can be exposed. In this case, the dielectric layer 2506 at or around the side surfaces of the opening (e.g., formed via the one or more etching processes) can remain, such as on the side surface of at least one of the channel region, the hardmask layer 2006, or the PO material 1306 (e.g., a gate structure extending along a second lateral direction different from the channel region(s)).

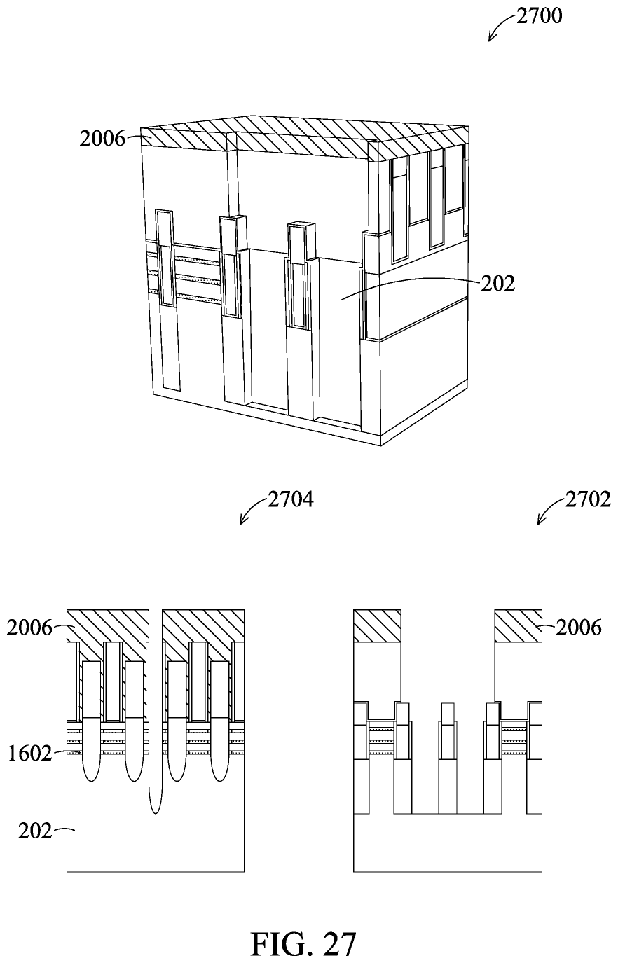

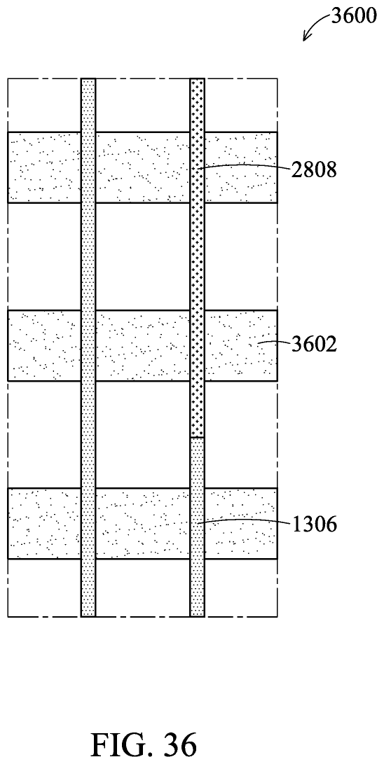

Corresponding to operation 142 of FIG. 1, FIG. 27 shows a perspective view 2700 and cross-sectional views 2702 and 2704 of the stack of layers undergoing the CPODE process. The cross-sectional view 2704 can correspond to or be associated with a cut along a lengthwise direction (e.g., a first or a second lateral direction) of the dielectric structure 2808 which can be better appreciated in the top view of FIG. 36. At this stage in the CPODE process, one or more directional etching processes (e.g., a part of a third etching process) are utilized to remove portions of the substrate 202, such as a lower portion of the channel region via a pulse signal described herein. The dielectric layer 2506 can be removed or etched as part of the etching process utilized at this stage. To remove the one or more portions of the stack of layers, particular etching processes can be utilized, for instance, to minimize at least one of STI recessing (e.g., less than 10 nm recessed) or remaining horn (e.g., less than 10 nm) of the substrate 202 (e.g., Si horn) around the bottom surface of at least one STI. Implementations that do not utilize the techniques described herein may cause excessive recessing of the STI or excessive remaining horn of the substrate 202 around the bottom of at least one STI during or after the etching process.

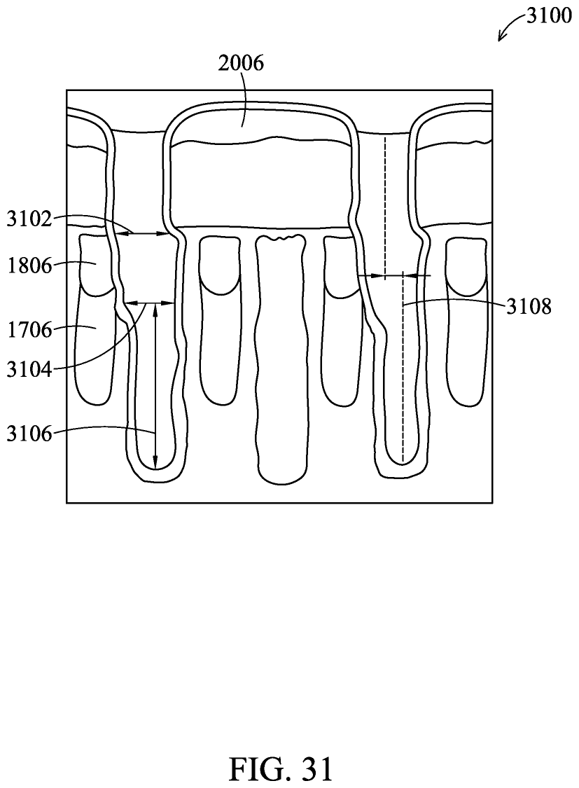

For example, to perform the etching process, particular etching conditions can be utilized to minimize STI loss, and Si horn, and to achieve the results described herein. As described in conjunction with FIG. 33, when the etching process reaches the boundary 3306 or continuing to region 3308, an Si etching process can be performed to remove a portion of the substrate 202 (shown in FIG. 27). The gas used in the etching process can involve using about 100 to about 1000 sccm of HBr, about 0 to about 100 sccm of O₂, and about 100 to about 1000 sccm of Ar gas. Example cross-sectional photographs of a result of the CPODE process are shown in at least FIGS. 31-33. An example diagram of a top view of a result of the CPODE process is shown in FIG. 36.

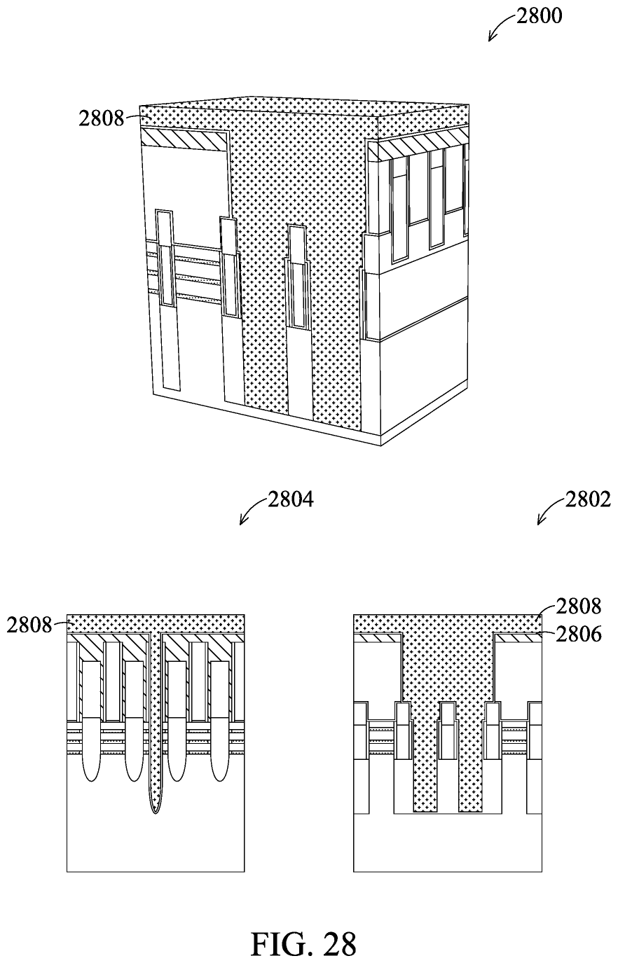

Referring to FIG. 36, shows an example diagram of a top view 3600 of a result of a CPODE process that is used to isolate (or pattern) one or more transistor devices, in accordance with some embodiments. As shown, in the top view 3600, the CPODE process can be used to isolate individual transistor structures 3602 (e.g., respective gate structures, such as PO material 1306) from one another by etching and replacing portions of the PO material 1306 and replacing with a dielectric filler material 2808 (described in greater detail in connection with FIG. 28). Using the present techniques, the etching process to isolate the transistor structures described herein does not damage any portions of the transistor structures (e.g., minimize bowing of the PO material 1306, minimize STI recess, minimize Si horn, avoid damages to the epitaxial structures, etc.), resulting in reduced leakage current.

FIG. 31 shows a cross-sectional photograph 3100 of a stack of layers described herein, which has undergone an etching process using the techniques described herein. As shown, even with one or more overlaps, damages to the epitaxial structures (e.g., doped semiconductor material 1706) can be minimized or avoided, as the structures are self-aligned. Although an overlap shift is presented (e.g., around 6 nm in this case), the etched regions can remain substantially vertical, with minimal to no damage to the epitaxial structure. In this example, measurements were taken for dimensions of the opening formed via one or more etching processes. For instance, the measurement 3102 for the top portion of the ILD material 1806 can include an average width of 26.7 nm, a maximum width of 27.5 nm, and a minimum width of 25.2 nm. The measurement 3104 for the bottom portion of the ILD material 1806 (or the top portion of the first doped semiconductor material 1706) can include an average width of 23.2 nm, a maximum width of 26.1 nm, and a minimum width of 21.3 nm. The measurement 3106 from the portion of the measurement 3104 to the bottom of the opening can include an average depth of 65.1 nm, a maximum depth of 66.3 nm, and a minimum depth of 63.0 nm. The measurement 3108 for example overlap shifts can include an average shift of 5.8 nm, a maximum shift of 7.3 nm, and a minimum shift of 4.8 nm.

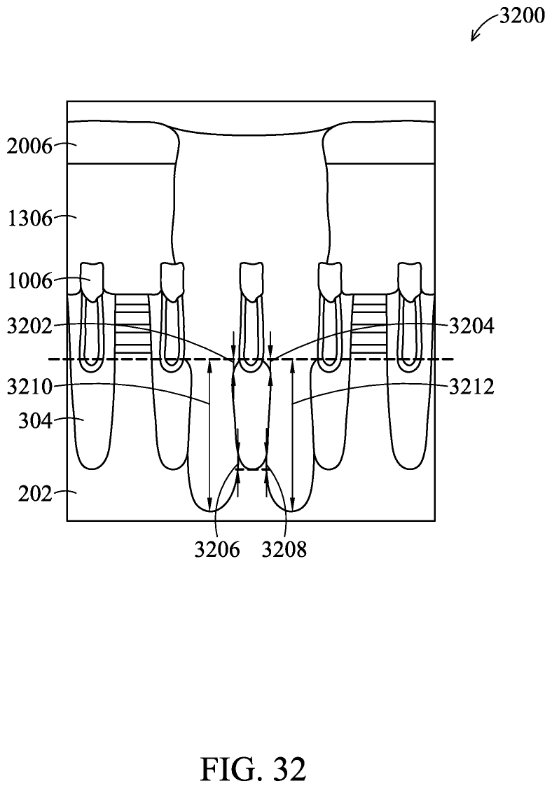

FIG. 32 shows a cross-sectional photograph 3200 of a stack of layers similar to that shown in FIG. 27, which has undergone an etching process using the techniques described herein. As shown, the recessing of the STI (e.g., the second dielectric material 304) and the remaining horn of the substrate 202 (sometimes referred to as a Si horn) around the bottom of the STI are minimized or reduced, such as under about 10 nm. In some embodiments, the recessing of the STI may be referred to as a recessed distance of an upper portion of the STI, and the remaining horn of the substrate may be referred to as a protruding distance of a portion of the substrate that extends along a lower portion of the STI.

As a representative example, measurements were taken for dimensions of one or more STI (e.g., isolation structures), the substrate 202, and the depth of the opening at the bottom portion of the channel region. For instance, the measurement 3202 for the upper left portion of the STI recess can include a depth averaged at about 9.1 nm, or within a range from about 6.8 nm to about 10 nm. The measurement 3204 for the upper right portion of the STI recess can include a depth averaged at about 8.9 nm, or within a range from about 6 nm to about 12.1 nm. As such, a ratio of the recessing of the STI to a height of the STI is less than about 0.15, in some embodiments. The measurement 3206 for the remaining horn of the substrate 202 at the bottom left portion of the STI can include a depth averaged at about 7.7 nm, or within a range from about 6.4 nm to about 9.4 nm. The measurement 3208 for the remaining horn of the substrate 202 at the bottom right portion of the STI can include a depth averaged at about 6.2 nm, or within a range from about 5.8 nm to about 6.7 nm. The measurement of 3210 for the depth of the lower portion of a first channel region (e.g., the region 3308 in conjunction with FIG. 33) can include a depth averaged at about 174.9 nm, or within a range from about 168.8 nm to about 179.8 nm. The measurement of 3212 for the depth of the lower portion of a second channel region can include a depth averaged at about 176.7 nm, or within a range from about 172.2 nm to about 179.8 nm. As such, a ratio of the remaining horn of the substrate to a height of the STI is less than about 0.11, in some embodiments.

FIG. 33 shows an example cross-sectional photograph of transistor devices subjected to the etching processes, made by the method of at least method of FIG. 1 with an overlay showing various etching stages used to carry out the CPODE techniques that do not result in transistor damage. The etching process tools used to implement the present techniques can include an inductively coupled plasma (ICP) or dipole antenna plasma source driven by a radio-frequency (RF) power generator. Example frequencies of 13.56 MHz or 27 MHz may be utilized. The process chamber may be operated at a pressure in a range of about 3 mTorr to about 150 mTorr and a temperature of about 20 degrees Celsius to about 140 degrees Celsius. The RF power generator can be operated to provide source power between about 100 W to about 1500 W, and the output of the RF power generator can be controlled by a pulse signal having a duty cycle in a range of about 20% to 100%. An RF bias power can be provided to the pedestal, which can have a range of about 10 W to about 600 W.

As described above, one or more etching processes can be used to remove portions of the stack of layers. For instance, the first etching process can be utilized for etching regions at or above the boundary 3302 including removing at least a portion of the PO material 1306. Further, the second etching process can be utilized to remove one or more layers of the sacrificial material 204 and one or more layers of the substrate 202 (e.g., the channel region), such as in region 3304. Additionally, the third etching process can be utilized to remove portions of the substrate 202 (e.g., the lower portion of the channel region), such as at or below the boundary 3306, in region 3308.

Corresponding to operation 144 of FIG. 1, FIG. 28 shows a perspective view 2800 and cross-sectional views 2802 and 2804 of the stack of layers following the deposition of one or more dielectric materials in the etched region of the device. The cross-sectional view 2802 can correspond to or be associated with a cut along a lengthwise direction (e.g., a first or a second lateral direction) of the dielectric structure 2808 which can be better appreciated in the top view of FIG. 36. The cross-sectional view 2804 can correspond to or be associated with a cut along a lengthwise direction (e.g., the other second or first second lateral direction) of the dielectric structure 2808 which can be better appreciated in the top view of FIG. 36. As shown, a first thin layer of a dielectric fill material 2806 is first deposited over the entire device. The dielectric fill material 2806 can be any suitable dielectric material, including silicon oxide, silicon oxynitride, or the like. After forming the layer of the dielectric fill material 2806, a second dielectric fill material 2808 can be formed (e.g., filled in the opening formed via the various etching processes). The second dielectric fill material 2808 can be formed of silicon nitride, silicon oxynitride, silicon carbonitride, or the like. The dielectric fill material 2806 and the second dielectric fill material 2808 can each be formed using a suitable material deposition technique, such as ALD, CVD, PVD, FCVD, or the like. Forming the second dielectric fill material 2808 can thereby electrically isolating the corresponding pair of epitaxial structures of the channel region from each other, for example.

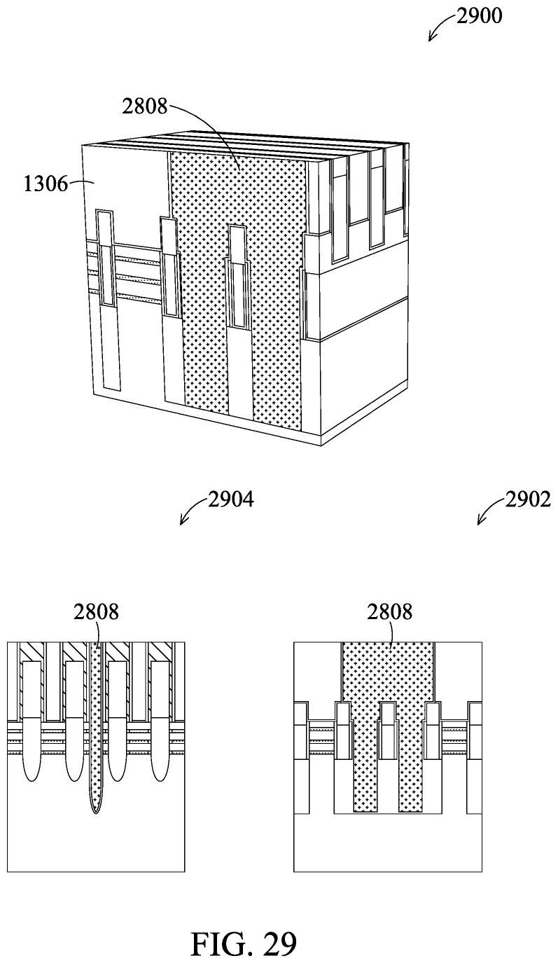

Still corresponding to operation 144 of FIG. 1, FIG. 29 shows a perspective view 2900 and cross-sectional views 2902 and 2904 of the stack of layers after a CMP process has been performed. After the second dielectric fill material 2808 has been deposited, a planarization process, such as a CMP process, may be performed to achieve a level upper surface for the device. The CMP may also remove the hardmask layer 2006 and the upper portions of the dielectric fill material 2806. After the planarization process, the upper surface of the second dielectric fill material 2806 is level with the upper surface of the PO material 1306, in some embodiments.

In various implementations, the PO material 1306 (or one or more other structures or materials) can be removed (e.g., for replacement with active gate structures or materials. For example, the PO material 1306, the fourth dielectric material 1204, and the sacrificial material 204 can be removed. Following the removal, a number of active (e.g. metal) gate structures (not shown) can be formed. For instance, the PO material 1306, which previously acted as dummy gate structures, has been replaced with a number of active gate structures. Each of the active gate structures can thus wrap around a respective number of substrate layers 202. As shown in conjunction with FIG. 36, the active gate structures (e.g., associated with the position of the PO structure 1306) can be physically and electrically isolated from each other by the dielectric structure 2808. With the dielectric structure 2808 formed in the profiles as disclosed above, it may facilitate the formation of active gate structures.

The active gate structures can be formed on the channel regions to create transistor devices in the stack of layers. The active gate structures can include a gate dielectric layer, a metal gate layer, and one or more other layers, which are not separately shown for clarity. For example, each of the active gate structures may further include a capping layer and a glue layer. The capping layer can protect the underlying work function layer from being oxidized. In some embodiments, the capping layer may be a silicon-containing layer, such as a layer of silicon, a layer of silicon oxide, or a layer of silicon nitride. The glue layer can function as an adhesion layer between the underlying layer and a subsequently formed gate electrode material (e.g., tungsten) over the glue layer. The glue layer may be formed of a suitable material, such as titanium nitride.

The gate dielectric layers can be each deposited to surround the semiconductive material that is grown on the layers of the substrate 202. The gate dielectric layers may include silicon oxide, silicon nitride, or multilayers thereof. In example embodiments, the gate dielectric layers each include a high-k dielectric material, and in these embodiments, the gate dielectric layers may each have a k value greater than about 7.0, and may include a metal oxide or a silicate of Hf, Al, Zr, La, Mg, Ba, Ti, Pb, or combinations thereof. The formation methods of the gate dielectric layers may include molecular beam deposition (MBD), ALD, and the like. A thickness of each of the gate dielectric layers may be between about 8 angstroms (Å) and about 20 Å, as an example.

The metal gate layers can each be formed over the respective gate dielectric layer. The metal gate layer can be formed in the region previously occupied by the PO material 1306. The metal gate layers may each be a P-type work function layer, an N-type work function layer, multilayers thereof, or combinations thereof, in some embodiments. Accordingly, the metal gate layers may each be referred to as a work function layer, in some embodiments. In the discussion herein, a work function layer may also be referred to as a work function metal. Example P-type work function metals that may be included in the gate structures for P-type devices include TiN, TaN, Ru, Mo, Al, WN, ZrSi₂, MoSi₂, TaSi₂, NiSi₂, WN, other suitable P-type work function materials, or combinations thereof. Example N-type work function metals that may be included in the gate structures for N-type devices include Ti, Ag, TaAl, TaAlC, TiAlN, TaC, TaCN, TaSiN, Mn, Zr, other suitable N-type work function materials, or combinations thereof.

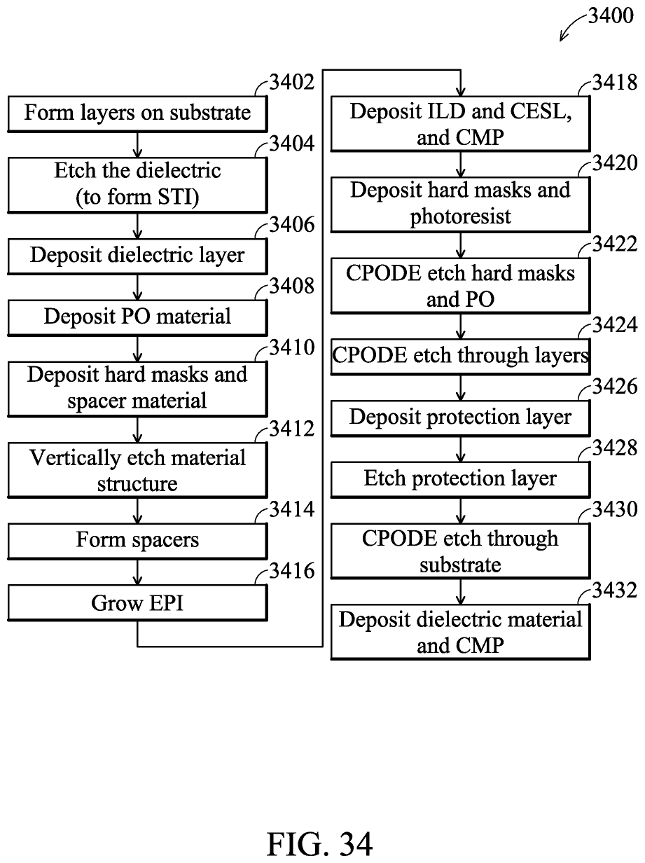

Referring now to FIG. 34, depicted is a flowchart of an example method 3400 for making transistor devices in connection with the CPODE processes described herein, in accordance with some embodiments. For example, at least some of the operations (or steps) of the method 3400 can be used to form transistor devices, such as a nanosheet transistor devices, fin field-effect transistor (FinFET) devices, nanowire transistor devices, vertical transistor devices, or the like, and to electrically isolate the transistor devices from one another according to a predetermined design using CPODE techniques. It is noted that the method 3400 is merely an example, and is not intended to limit the present disclosure. Accordingly, it is understood that additional operations may be provided before, during, and after the method 3400 of FIG. 34, and that some other operations may only be briefly described herein. Additionally, operations of the method 3400 may be performed in an order different from that described herein to achieve desired results. In some embodiments, operations of the method 3400 may be associated with the various perspective and cross-sectional views of the transistor devices at various fabrication stages as shown in FIGS. 2-29, such as similar to FIG. 1, which will be discussed in further detail below.

In brief overview, the method 3400 starts with operation 3402 of forming layers on a substrate. The method 3400 continues to operation 3404 of etching the dielectric (e.g., to form STI). The method 3400 continues to operation 3406 of depositing a dielectric layer. The method 3400 continues to operation 3408 of depositing a polysilicon (PO) material. The method 3400 continues to operation 3410 of depositing hardmasks and spacer material. The method 3400 continues to operation 3412 of vertically etching the material structure. The method 3400 continues to operation 3414 of forming spacers. The method 3400 continues to operation 3416 of epitaxially growing semiconductor material. The method 3400 continues to operation 3418 of forming an interlayer dielectric (ILD), a contact etch stop layer (CESL), and performing a CMP process. The method 3400 continues to operation 3420 of depositing hardmasks and photoresist. The method 3400 continues to operation 3422 of CPODE etching hardmasks and PO. The method 3400 continues to operation 3424 of CPODE etching through one or more layers. The method 3400 continues to operation 3426 of depositing at least one protection layer. The method 3400 continues to operation 3428 of etching the protection layer. The method 3400 continues to operation 3430 of CPODE etching through substrate. The method 3400 continues to operation 3432 of depositing a dielectric and performing a CMP process.

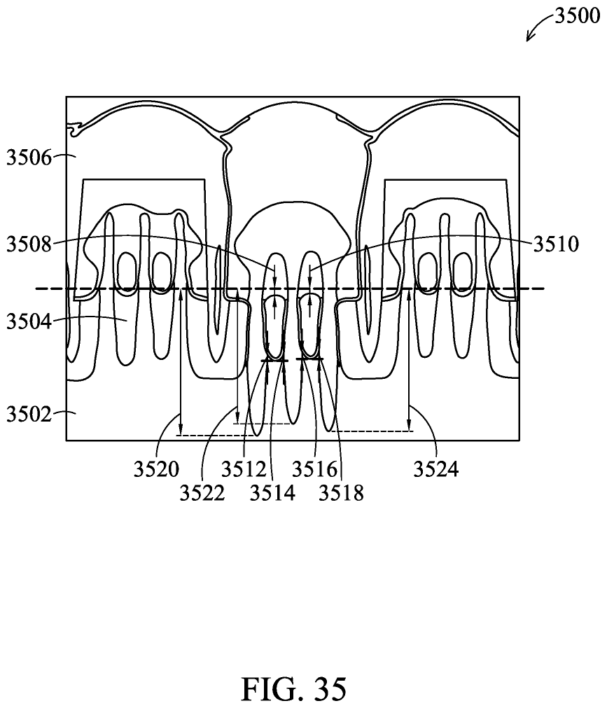

In various implementations, the one or more operations of method 3400 can include, correspond to, or be a part of one or more operations of method 100, such as described in conjunction with FIG. 1. The one or more operations of method 3400 can correspond to at least one of FIGS. 2-29. For instance, the operation 3402 can include features described in conjunction with FIG. 2. At this stage, a stack of layers can be formed on a semiconductor substrate, and can include a number of alternating layers of the substrate material (e.g., substrate material 202) and a first sacrificial material (e.g., sacrificial material 204). A hardmask material (e.g., hardmask material 206) can be deposited on the top layer of the sacrificial material. In some cases, the layers on the substrate at this stage may include the substrate material without other types of materials, for example. The substrate material can correspond to substrate material 3502 shown in FIG. 35.

The substrate may be a semiconductor substrate, such as a bulk semiconductor, an SOI substrate, or the like, which may be doped (e.g., with a p-type or an n-type dopant) or undoped. The substrate may be a wafer, such as a silicon wafer. Generally, an SOI substrate includes a layer of a semiconductor material formed on an insulator layer. The insulator layer may be, for example, a BOX layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The one or more layers of the sacrificial material may be formed on the substrate material using a material deposition process or an epitaxial growth process. The sacrificial material can be removed in later process steps, and can be formed from a material that has different material properties than the substrate material, to facilitate selective removal or deposition techniques described herein. The sacrificial material can be an alloy semiconductor material, such as SiGe.

At operation 3404, a suitable etching process can be applied to the stack of layers. For example, the suitable etching process can be performed on the structure formed at operation 3402 to create or form an STI (e.g., STI structure). The features of operation 3404 can include or be described in conjunction at least one of operations 104 or 112 of FIG. 1, for example. Subsequently, at operation 3406, a dielectric material (e.g., such as similar to the fourth dielectric material 1204) can be formed as a thin layer over the top of the device. The dielectric material can be any type of suitable insulating material, such as an oxide material. The dielectric material can be formed using any type of suitable material deposition technique, such as CVD, PVD, ALD, or other suitable processes. The dielectric material can electrically isolate the substrate material from additional material layers added in future process steps.

At operation 3408, a PO material (e.g., PO material 3506 shown in conjunction with FIG. 35, such as similar to PO material 1306) can cover the entirety of the device, and is deposited over the various structures of the device as described in operation 3406, for example. The operation 3408 can include one or more features, steps, or operations similar to operation 120 of FIG. 1. For example, the PO material can be, for example, a polysilicon material. The PO material can be used as a placeholder region, which will be removed in layer process steps to form metal gate materials. The PO material can be deposited using any suitable material deposition technique, including ALD, CVD, PVD, among other techniques. PO material 1306 can be deposited to a predetermined thickness, according to design parameters of the device.

At operation 3410 (e.g., similar to operation 122 of FIG. 1), the patterning and etching the of the PO material can be performed. To etch the PO material, one or more hardmasks (e.g., similar to a third hardmask 1410 and a fourth hardmask 1408) can first be patterned on top of the PO material. The one or more hardmarks can be patterned, for example, using a photo resist material, such that the one or more hardmarks form strips that are perpendicular to the fin structures formed from the sacrificial material and the substrate material. After depositing the one or more hardmarks, the PO material can be selectively and vertically etched, such that the PO material below the one or more hardmarks are not removed by the etching process. Any suitable vertical etching process or material removal process can be used.

In some cases, after etching the PO material, a layer of a liner material (e.g., similar to the second liner material 1412) can be deposited over the top of the device, covering the PO material, the one or more hardmasks, the substrate material, the high-k dielectric material, among other materials of the device. The second liner material can be any type of suitable insulating material, such as an oxide or another type of insulator. After depositing the second liner material, a layer of a spacer material (e.g., similar to the spacer material 1406) can be deposited over the device. As shown, the layer of the spacer material evenly covers all materials on the surface of the device. The spacer material can be deposited using any suitable material deposition technique, such as ALD, CVD, PVD, among others. The spacer material can be used to protect materials on the device from etching processes in further process steps.

At operation 3412 a vertical etching process can be performed. The etching process of operation 3412 can be performed using any suitable etching technique, such as in similar manner as described in operation 124, for instance, shown in conjunction with FIG. 15. At operation 3414, one or more spacers (e.g., similar to spacer 1602) can be formed on at least one of the substrate material or the sacrificial material. For example, the operation 3414 for forming the spacer can be described in a similar manner as operation 126 of FIG. 1 (e.g., shown in conjunction with FIG. 16). The spacers can be formed from any type of suitable insulating material with a relatively low dielectric constant k, such as silicon oxide, silicon oxycarbonitride (SiOCN), or the like. Any suitable deposition method, such as thermal oxidation, CVD, or the like, may be used to form the spacers. The spacers can be deposited or formed in any shape or size.

At operation 3416, a doped semiconductor material can be epitaxially grown (e.g., sometimes referred to as an epitaxial structure or material). The operation 3416 can include features or functionalities similar to operation 128 of FIG. 1 (e.g., similarly shown in FIG. 17). Multiple doped semiconductor materials can be grown, such as a first doped semiconductor material and a second doped semiconductor material. Each of the doped semiconductor materials can be epitaxially grown using the substrate as a seed material in the troughs formed in previous etching steps. To form each of doped semiconductor materials, selective patterning may be performed to guide the epitaxial growth of the doped semiconductor materials in respective regions of each trough. For example, a dielectric material or other masking material may be used to prevent epitaxial growth on some regions of the substrate material, allowing for selective growth of both P-type and N-type semiconductive material.

At operation 3418, an ILD material and CESL material can be deposited and a planarization process can be performed subsequent to depositing the ILD and CESL materials. For example, the deposition of the ILD and CESL materials of operation 3418 can be described in a similar manner as operation 130 of FIG. 1. For instance, the ILD material and the CESL material can be deposited using any suitable deposition techniques similar to the deposition of ILD material 1806 and the CESL material 1810, respectively. After these formations, a planarization process, such as a CMP process, may be performed to achieve a level upper surface for the dielectric layer. The CMP may also remove the one or more hardmasks. In some cases, the CMP process can remove at least a portion of the CESL material. After the planarization process, the upper surface of the dielectric layer is level with the upper surface of the PO material, in some embodiments.

At operation 3420, a hardmask layer and a patterned photoresist can be formed. The formation of the hardmask layer and the patterned photoresist can be similar to operation 132 of FIG. 1. For example, at the start of the CPODE process, a hardmask layer (e.g., similar to hardmask layer 2006) can be deposited over the surface of the device. The hardmask layer can be any type of suitable dielectric material, including as silicon nitride, silicon carbonitride, or the like, and may be formed using a suitable method such as CVD, PECVD, or FCVD. After the hardmask layer 2006 is formed, a planarization process, such as a CMP process, may be performed. In some cases, one or more additional hardmask layers (e.g., similar to the second hardmask layer 2110 or the third hardmask layer 2108) can be formed on top of the initial hardmask layer, followed by a layer of patterned photoresist (e.g., similar to patterned photoresist 2106). The patterned photoresist can include a slot-shaped opening, which is positioned to guide further etching processes. To pattern the photoresist, the photoresist is deposited, irradiated (exposed), and developed to remove predetermined portions of the photoresist. The remaining photoresist protects the underlying layers from subsequent processing steps, such as etching.

At operation 3422, the device (e.g., the stack of layers) can undergo the CPODE process to isolate one or more transistor structures that will be formed in the stack of layers. The operation 3422 can be performed or described in similar manner as operation 134 of FIG. 1. As For example, using suitable etching processes, each of the photoresist and one or more hardmasks can be removed, along with a slot-shaped portion of the hardmask. The slot-shaped portion that is removed from the hardmask may be previously defined by the corresponding opening in the photoresist. The etching process can be a vertical etching process towards the PO material, with the PO material serving as an etch stop layer.

Still referring to operation 3422, an additional vertical etching process in the direction towards the substrate can be performed to remove a portion of the PO material (e.g., at least a part of a first etching process). Any suitable etching process, such as a dry etching process or a wet etching process, can be used to remove the PO material. For instance, the etching process can involve at least one of TCP or ICP etching technique(s) for directionally removing the PO material. The fourth dielectric material can act as an etch-stop for the etching process. The etching process can be directional, such that the PO material is removed in the predetermined slot-shape defined by the hardmask layer.

For example, to perform the etching process, particular etching conditions can be utilized to minimize or avoid bowing or contorting the side surface(s) of the PO material and to achieve the results described herein. As the vertical etch is performed from the top of the device towards the bottom, the etching process begins by etching through the hardmask and the PO material. Any suitable etching technique can be used to remove the PO material. For example, the CPODE etching process can include or involve directional etching of the PO material to control the bowing, such as by configuring at least one of O₂ flush time (or rate), Ar sputter time (or rate), and/or the cycle of at least one of SiCl₄, N₂, O₂, and/or chlorine, among others. For instance, the gas used in the etching process of the PO material 1306 can involve using an O₂ flush of 100-200 sccm, Ar sputter including CF₄ of 0-100 sccm and Ar of 500-1000 sccm, the cycle including SiCl₄ of 0-50 sccm, N₂ of 0-100 sccm, O₂ of 0-100 sccm, and Cl₂ of 100-500 sccm, etc. Hence, as shown in the before and after comparison, utilizing the etching process can minimize or control the bowing of the PO material, providing a comparatively vertical or linear side surface of the PO material. This can prevent any unintended short-circuits, current leakage, or logic circuits that do not function properly.

At operation 3424, additional CPODE etching process can be performed through the stack of layers. The etching process of operation 3424 can include or correspond to the features of operation 136 of FIG. 1. At this stage in the CPODE process, one or more directional etching processes (e.g., at least a part of a second etching process) are utilized to remove at least one portion of the stack of layers, such as the fourth dielectric material layer, one or more layers of the substrate 202, and one or more layers of the sacrificial material that are positioned beneath the slot defined by the hardmask layer. In some cases, the layers of substrate and the one or more layers of the sacrificial material can correspond to or be a part of a channel region of various channel regions of the stack of layers. To remove a portion of one or more channel regions, particular etching processes can be utilized to minimize the loss of STI material (e.g., STI material 3504 in conjunction with FIG. 35) or reduce recessing of the STI material (e.g., less than 10 nm STI recess).

For example, to perform the etching process, particular etching conditions can be utilized to minimize STI loss and to achieve the results described herein. When the etching process (e.g., the etching process described in a similar manner as in FIG. 33) reaches the boundary 3302, a low-selective etching process can be used to break through the fourth dielectric material layer. The gas used in the etching process can involve using about 0 to about 200 sccm of CF₄, and about 100 to about 1000 sccm of Ar gas. Once the oxide layer has been etched, the direction etching process can continue in the region 3304 (e.g., including or associated with one or more channel regions). In this region, a highly selecting etching process of the substrate to the spacers can be performed, in addition to SiO deposition process. The substrate etching process can utilize about 100 to about 1000 sccm of HBr, about 0 to about 100 sccm of O₂, and about 100 to about 1000 sccm of Ar.

At operation 3426, at least one protection layer (e.g., dielectric layer) can be deposited. The features of operation 3426 can include or correspond to the features of operation operation 138. For instance, the protection layer can be deposited using at least one suitable deposition technique, such as SiO deposition process. The protection layer can cover the entirety the device at this stage. The SiO deposition process can involve a deposition process and an oxidization process. For example, the deposition process can be performed using about 0 to about 100 sccm of SiCl₄, about 100 to about 500 sccm of HBr, and about 100 to about 1000 sccm of Ar. The oxidization process can be performed with about 10 to about 200 sccm of O₂.

At operation 3428, at least a portion of the protection layer can be etched. The features of operation 3428 can include or correspond to the one or more features of operation 140 of FIG. 1. For example, after the SiO deposition process, a portion of the dielectric layer (e.g., protection layer) can be etched using a suitable etching technique. For example, a low-selective etching process can be used to break through the protection layer. The gas used in the etching process can involve using about 0 to about 200 sccm of CF₄, and about 100 to about 1000 sccm of Ar gas. Once the low-selective etching process is performed, the top surface of hardmask layer (e.g., the top surface of the device) and at least a portion of the surface of the substrate (e.g., substrate 3502 shown in conjunction with FIG. 35) can be exposed.

At operation 3430, another CPODE process can be performed. The CPODE process of operation 3430 may include similar features or correspond to the CPODE process of operation 142 of FIG. 1. For example, at this stage in the CPODE process, one or more directional etching processes (e.g., a part of a third etching process) are utilized to remove portions of the substrate 202, such as a lower portion of the channel region. The protection layer can be removed or etched as part of the etching process utilized at this stage. To remove the one or more portions of the stack of layers, particular etching processes can be utilized, for instance, to minimize at least one of STI recessing (e.g., less than 10 nm recessed) or remaining horn (e.g., less than 10 nm) of the substrate (e.g., Si horn) around the bottom surface of at least one STI. Implementations that do not utilize the techniques described herein may cause excessive recessing of the STI or excessive remaining horn of the substrate around the bottom of at least one STI during or after the etching process.

For example, to perform the etching process, particular etching conditions can be utilized to minimize STI loss, and Si horn, and to achieve the results described herein. As described in conjunction with FIG. 33, when the etching process reaches the boundary 3306 or continuing to region 3308, an Si etching process can be performed to remove a portion of the substrate. The gas used in the etching process can involve using about 100 to about 1000 sccm of HBr, about 0 to about 100 sccm of O₂, and about 100 to about 1000 sccm of Ar gas. Example cross-sectional photographs of a result of the CPODE process are shown in at least FIG. 35. An example diagram of a top view of a result of the CPODE process is shown in FIG. 36 (e.g., similar to the operations of method 100).

At operation 3432, a dielectric fill material can be deposited in the opening formed by the one or more etching processes. The features of operation 3432 can include features similar to operation 144 of FIG. 1. For example, a first thin layer of a dielectric fill material is first deposited over the entire device. The dielectric fill material can be any suitable dielectric material, including silicon oxide, silicon oxynitride, or the like. After forming the layer of the dielectric fill material (e.g., dielectric fill material 2806), a second dielectric fill material (e.g., second dielectric fill material 2808) can be formed. The second dielectric fill material can be formed of silicon nitride, silicon oxynitride, silicon carbonitride, or the like. The dielectric fill material and the second dielectric fill material can each be formed using a suitable material deposition technique, such as ALD, CVD, PVD, FCVD, or the like.

Still referring to operation 3432 of FIG. 34, a CMP process can be performed (e.g., similar to features of operation 144 of FIG. 1). After the second dielectric fill material has been deposited, a planarization process, such as a CMP process, may be performed to achieve a level upper surface for the device. The CMP may also remove the hardmask layer (e.g., hardmask layer 2006) and the upper portions of the dielectric fill material. After the planarization process, the upper surface of the second dielectric fill material is level with the upper surface of the PO material, in some embodiments.

FIG. 35 shows a cross-sectional photograph 3500 of a stack of layers, which has undergone an etching process using the techniques described in the method 3400 of FIG. 34. As shown, the recessing of the STI material 3504 and the remaining horn of the substrate 3502 (sometimes referred to as a Si horn) around the bottom of the STI material can be minimized or reduced utilizing the etching processes described herein, such as under about 10 nm. In some embodiments, the recessing of the STI may be referred to as a recessed distance of an upper portion of the STI, and the remaining horn of the substrate may be referred to as a protruding distance of a portion of the substrate that extends along a lower portion of the STI.

As a representative example, measurements were taken for dimensions of one or more STI material 3504 (e.g., isolation structures), the substrate 3502, and the depth of the opening at the bottom portion of the channel region. For instance, the measurement 3508 for the central recess region of a first STI material can include a depth averaged at about 3.6 nm, or within a range from about 1.6 nm to about 4.6 nm. The measurement 3510 for the central recess region of a second STI material can include a depth averaged at about 3.4 nm, or within a range from about 2.2 nm to about 5 nm. As such, a ratio of the recessing of the STI to a height of the STI is less than about 0.1, in some embodiments. The measurement 3512 for the remaining horn lower left of the first STI material can include a depth averaged at about 1.3 nm, or within a range from about 1.1 nm to about 1.8 nm. The measurement 3514 for the remaining horn lower right of the first STI material can include a depth averaged at about 2.4 nm, or within a range from about 0.9 nm to about 5.4 nm. The measurement 3516 for the remaining horn lower left of the second STI material can include a depth averaged at about 1.3 nm, or within a range from about 1 nm to about 1.8 nm. The measurement 3518 for the remaining horn lower right of the second STI material can include a depth averaged at about 1.3 nm, or within a range from about 0 nm to about of 3.1 nm. The measurement 3520 for the depth of a first channel region can include a depth averaged at about 165.4 nm, or within a range from about 161.9 nm to about 167.5 nm. The measurement 3522 for the depth of a second channel region can include a depth averaged at about 160.8 nm, or within a range from about 157.6 nm to about 163.8 nm. The measurement 3524 for the depth of a second channel region can include a depth averaged at about 162.5 nm, or within a range from about 160.4 nm to about 165.7 nm. As such, a ratio of the remaining horn of the substrate to a height of the STI is less than about 0.1, in some embodiments.

In one aspect of the present disclosure, a method for fabricating semiconductor devices is disclosed. The method includes forming a plurality of channel regions over a substrate. The plurality of channel regions, in parallel with one another, extend along a first lateral direction. Each of the plurality of channel regions includes at least a respective pair of epitaxial structures. The method includes forming a gate structure over the plurality of channel regions, wherein the gate structure extends along a second lateral direction. The method includes removing, through a first process, a portion of the gate structure that was disposed over a first one of the plurality of channel regions. The method includes removing, through a second process, a portion of the first channel region. The second process includes at least one silicon process and at least one silicon oxide deposition process. The method includes removing, through a third process controlled based on a pulse signal, a portion of the substrate that was disposed below the removed portion of the first channel region.

In another aspect of the present disclosure, a method for fabricating semiconductor devices is disclosed. The method includes forming a plurality of channel regions over a substrate, wherein the plurality of channel regions, in parallel with one another, extend along a first lateral direction. The method includes forming a plurality of isolation structures. Each of the plurality of channel regions has a lower portion embedded by a corresponding pair of the isolation structures. The method includes forming a first gate structure over the plurality of channel regions, wherein the first gate structure extends along a second lateral direction. The method includes forming a plurality of pairs of epitaxial structures, wherein each of the pairs of epitaxial structures is disposed on opposite sides of the first gate structure. The method includes removing, through a first process, a portion of the first gate structure that was disposed over a first one of the plurality of channel regions. The method includes removing, through a second process, a portion of the first channel region. The method includes removing, through a third process, a portion of the substrate that was disposed below the removed portion of the first channel region. The method includes filling, with a dielectric material, an opening formed through the first to third processes. The method includes replacing a remaining portion of the first gate structure with a second gate structure. A first ratio of a maximum recessed distance of an upper portion of each of a first one and a second one of the isolation structures separated by the first channel region to a total height of the isolation structures is less than about 0.15, and wherein a second ratio of a maximum protruding distance of a portion of the substrate that extends along a lower upper portion of each of the first and second isolation structures to the total height of the isolation structures is less than about 0.11.

In yet another aspect of the present disclosure, a semiconductor device is disclosed. The semiconductor device includes a first channel region and a second channel region. The first and second channel regions extend in a first lateral direction and are in parallel with each other. The semiconductor device includes a dielectric structure interposed between the first channel region and the second channel region along a second lateral direction perpendicular to the first lateral direction. The semiconductor device includes a first isolation structure disposed adjacent a lower portion of the first channel structure. The semiconductor device includes a second isolation structure disposed adjacent a lower portion of the second channel structure. The first and second isolation structures have a height. The dielectric structure includes a portion interposed between the first and second isolation structures. A first ratio of a maximum recessed distance of an upper portion of each of the first and second isolation structures to the height is less than about 0.1, and wherein a second ratio of a maximum protruding distance of a portion of the substrate that extends along a lower portion of each of the first and second isolation structures to the height is less than about 0.1.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for fabricating semiconductor devices, comprising:
forming a plurality of channel regions over a substrate, wherein the plurality of channel regions, in parallel with one another, extend along a first lateral direction, and wherein each of the plurality of channel regions includes at least a respective pair of epitaxial structures;
forming a gate structure over the plurality of channel regions, wherein the gate structure extends along a second lateral direction;
removing, through a first process, a portion of the gate structure that was disposed over a first one of the plurality of channel regions;
removing, through a second process, a portion of a first channel region, wherein the second process includes at least one silicon etching process and at least one silicon oxide deposition process; and
removing, through a third process controlled based on a pulse signal, a portion of the substrate that was disposed below the removed portion of the first channel region.

2. The method of claim 1, wherein the second process sequentially includes the at least one silicon etching process and a number of cycles of the at least one silicon oxide deposition process.

3. The method of claim 1, wherein, during the first to third processes, a remaining portion of the gate structure remains substantially intact.

4. The method of claim 1, wherein the at least one silicon oxide deposition process includes flowing at least one of the following gases: silane (SiCl₄), hydrogen bromide (HBr), argon (Ar), or oxygen (O₂).

5. The method of claim 1, wherein the channel regions have their respective lower portions, and wherein adjacent ones of the lower portions are separated from each other with a corresponding one of a plurality of isolation structures.

6. The method of claim 5, wherein each of the plurality of channel regions includes a plurality of semiconductor layers vertically spaced from one another and in contact with the corresponding pair of epitaxial structures.

7. The method of claim 6, wherein a ratio of a maximum recessed distance of an upper portion of each of a first one and a second one of the isolation structures separated by the first channel region to a total height of the isolation structures is less than about 0.15.

8. The method of claim 6, wherein a ratio of a maximum protruding distance of a portion of the substrate that extends along a lower upper portion of each of a first one and a second one of the isolation structures separated by the first channel region to a total height of the isolation structures is less than about 0.11.

9. The method of claim 1, further comprising filling, with a dielectric material, an opening formed through the first to third processes, thereby electrically isolating the corresponding pair of epitaxial structures of the first channel region from each other.

10. The method of claim 5, wherein each of the plurality of channel regions includes a one-piece structure and in contact with the corresponding pair of epitaxial structure.

11. The method of claim 10, wherein a ratio of a maximum recessed distance of an upper portion of each of a first one and a second one of the isolation structures separated by the first channel region to a total height of the isolation structures is less than about 0.1.

12. The method of claim 10, wherein a ratio of a maximum protruding distance of a portion of the substrate that extends along a lower upper portion of each of a first one and a second one of the isolation structures separated by the first channel region to a total height of the isolation structures is less than about 0.1.

13. A method for fabricating semiconductor devices, comprising:
forming a plurality of channel regions over a substrate, wherein the plurality of channel regions, in parallel with one another, extend along a first lateral direction;
forming a plurality of isolation structures, wherein each of the plurality of channel regions has a lower portion embedded by a corresponding pair of the isolation structures;
forming a first gate structure over the plurality of channel regions, wherein the first gate structure extends along a second lateral direction;
forming a plurality of pairs of epitaxial structures, wherein each of the pairs of epitaxial structures is disposed on opposite sides of the first gate structure;
removing, through a first process, a portion of the first gate structure that was disposed over a first one of the plurality of channel regions;
removing, through a second process, a portion of the first channel region;
removing, through a third process, a portion of the substrate that was disposed below the removed portion of the first channel region;
filling, with a dielectric material, an opening formed through the first to third processes; and
replacing a remaining portion of the first gate structure with a second gate structure,
wherein a first ratio of a maximum recessed distance of an upper portion of each of a first one and a second one of the isolation structures separated by the first channel region to a total height of the isolation structures is less than about 0.15, and wherein a second ratio of a maximum protruding distance of a portion of the substrate that extends along a lower upper portion of each of the first and second isolation structures to the total height of the isolation structures is less than about 0.11.

14. The method of claim 13, wherein at least one of the first to third processes is controlled based on a pulse signal.

15. The method of claim 13, wherein at least one of the first to third processes includes at least one silicon etching process and at least one silicon oxide deposition process.

16. The method of claim 13, wherein at least one of the first to third etching process sequentially includes the at least one silicon etching process and a number of cycles of the at least one silicon oxide deposition process.

17. The method of claim 13, wherein, during the first to third etching processes, a remaining portion of the first gate structure remains substantially intact.

18. A semiconductor device, comprising:
a first channel region and a second channel region formed over a substrate, wherein the first and second channel regions extend in a first lateral direction and are in parallel with each other;
a dielectric structure interposed between the first channel region and the second channel region along a second lateral direction perpendicular to the first lateral direction;
a first isolation structure disposed adjacent a lower portion of the first channel structure;
a second isolation structure disposed adjacent a lower portion of the second channel structure, wherein the first and second isolation structures have a height;
wherein the dielectric structure includes a portion interposed between the first and second isolation structures;
wherein a first ratio of a maximum recessed distance of an upper portion of each of the first and second isolation structures to the height is less than about 0.1, and wherein a second ratio of a maximum protruding distance of a portion of the substrate that extends along a lower portion of each of the first and second isolation structures to the height is less than about 0.1.

19. The semiconductor device of claim 18, wherein each of the first and second channel regions includes a plurality of semiconductor layers vertically spaced from one another.

20. The semiconductor device of claim 18, further comprising a plurality of epitaxial structures, wherein the first and second channel regions include at least a respective pair of the plurality of epitaxial structures.
